(19) United States
(12) Patent Application Publication
(10) Pub. No.: US 2026/0101632 A1
(43) Pub. Date: Apr. 9, 2026

(54) ORGANIC LIGHT-EMITTING DEVICE, DISPLAY PANEL, AND DISPLAY APPARATUS

(71) Applicant: Shanghai Tianma Micro-electronics Co., Ltd., Shanghai (CN)

(72) Inventors: Yu ZHANG, Shanghai (CN); Dongyang DENG, Shanghai (CN); Yupei ZHANG, Shanghai (CN); Long CHEN, Shanghai (CN)

(21) Appl. No.: 19/036,180

(22) Filed: Jan. 24, 2025

(30) Foreign Application Priority Data
Oct. 8, 2024 (CN) 202411401686.5

(51) Int. Cl. H10K 50/165; H10K 50/155; H10K 50/18; H10K 50/19; H10K 85/40; H10K 85/60; H10K 101/40; H10K 102/00

(52) U.S. Cl. CPC H10K 50/165; H10K 50/155; H10K 50/19; H10K 85/40; H10K 85/615; H10K 85/622; H10K 85/654; H10K 85/657; H10K 85/6572; H10K 85/6574; H10K 50/18; H10K 2101/40; H10K 2102/351

(57) ABSTRACT

An organic light-emitting device, a display panel and a display apparatus are provided. The organic light-emitting device includes an anode, two or more light-emitting units, and a cathode that are stacked one over another. Two adjacent light-emitting units of the two or more light-emitting units are connected through a charge generation layer. The charge generation layer includes an N-type charge generation layer, an intermediate layer, and a P-type charge generation layer that are stacked one over another. The N-type charge generation layer includes a first electron transport type organic material and an N-type dopant. The P-type charge generation layer includes a first hole transport type organic material and a P-type dopant. The intermediate layer has a property of transporting electrons and/or holes.

### CROSS-REFERENCE TO RELATED APPLICATION

The present disclosure claims priority of Chinese Patent Application No. 202411401686.5, filed on Oct. 8, 2024, the entire content of which is hereby incorporated by reference.

### FIELD OF THE DISCLOSURE

The present disclosure generally relates to the field of organic light-emitting technology and, more particularly, relates to an organic light-emitting device, a display panel and a display apparatus.

### BACKGROUND

As a new generation of display technology, organic light-emitting diodes (OLEDs), also known as organic electroluminescent (organic EL) diodes, may have advantages of ultra-thinness, self-luminescence, wide viewing angle, fast response, high light-emitting efficiency, good temperature adaptability, simple production process, low driving voltage, and low energy consumption. OLEDs have been widely used in industries such as flat panel display, flexible display, solid-state lighting and automotive display. Tandem OLED devices may be an effective approach to improve OLED efficiency and lifespan. Specifically, a tandem OLED device may be formed by vertically stacking two or more light-emitting units, and the light-emitting units are each connected through a charge generation layer. Compared with a traditional OLED, a tandem OLED has higher luminous brightness and current efficiency. The luminous brightness and current efficiency may increase exponentially with the increase in the number of light-emitting units connected in series. However, like a conventional OLED device, a tandem OLED device may have aging problems and problems with reduced stability. As such, the performance of tandem OLED devices needs to be further improved.

### SUMMARY

One aspect of the present disclosure includes an organic light-emitting device. The organic light-emitting device includes an anode, two or more light-emitting units, and a cathode that are stacked one over another. Two adjacent light-emitting units of the two or more light-emitting units are connected through a charge generation layer. The charge generation layer includes an N-type charge generation layer, an intermediate layer, and a P-type charge generation layer that are stacked one over another. The N-type charge generation layer includes a first electron transport type organic material and an N-type dopant. The P-type charge generation layer includes a first hole transport type organic material and a P-type dopant. The intermediate layer has a property of transporting electrons and/or holes.

Another aspect of the present disclosure includes a display panel. The display panel includes an organic light-emitting device. The organic light-emitting device includes an anode, two or more light-emitting units, and a cathode that are stacked one over another. Two adjacent light-emitting units of the two or more light-emitting units are connected through a charge generation layer. The charge generation layer includes an N-type charge generation layer, an intermediate layer, and a P-type charge generation layer that are stacked one over another. The N-type charge generation layer includes a first electron transport type organic material and an N-type dopant. The P-type charge generation layer includes a first hole transport type organic material and a P-type dopant. The intermediate layer has a property of transporting electrons and/or holes.

Another aspect of the present disclosure includes a display apparatus. The display apparatus includes a display panel. The display panel includes an organic light-emitting device. The organic light-emitting device includes an anode, two or more light-emitting units, and a cathode that are stacked one over another. Two adjacent light-emitting units of the two or more light-emitting units are connected through a charge generation layer. The charge generation layer includes an N-type charge generation layer, an intermediate layer, and a P-type charge generation layer that are stacked one over another. The N-type charge generation layer includes a first electron transport type organic material and an N-type dopant. The P-type charge generation layer includes a first hole transport type organic material and a P-type dopant. The intermediate layer has a property of transporting electrons and/or holes.

Other aspects of the present disclosure may be understood by those skilled in the art in light of the description, the claims, and the drawings of the present disclosure.

### BRIEF DESCRIPTION OF THE DRAWINGS

The following drawing is merely an example for illustrative purposes according to various disclosed embodiments and is not intended to limit the scope of the present disclosure.

FIG. 1 illustrates a schematic structural diagram of an organic light-emitting device consistent with the disclosed embodiments of the present disclosure.

The FIGURE includes following reference labels: 1, anode; 2, hole injection layer; 31, first light-emitting unit; 311, first hole transport layer; 312, first light-emitting layer; 313, first hole blocking layer; 314, first electron transport layer; 32, second light-emitting unit; 321, second hole transport layer; 322, second light-emitting layer; 323, second hole blocking layer; 324, second electron transport layer; 4, charge generation layer; 41, N-type charge generation layer; 42, intermediate layer; 43, P-type charge generation layer; 5, electron injection layer; 6, cathode; and 7, cap layer.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Technologies, methods, and equipment known to those of ordinary skill in relevant fields may not be discussed in detail, but where appropriate, these technologies, methods, and equipment should be regarded as part of the present disclosure.

It should be noted that, in the present disclosure, the highest occupied molecular orbital (HOMO) energy level value and the lowest unoccupied molecular orbital (LUMO) energy level value may be calculated by Gaussian software. A larger absolute value of the HOMO or LUMO energy level value indicates a deeper energy level.

It should be noted that, in the present disclosure, the electron mobility may be measured by a space-confined current method.

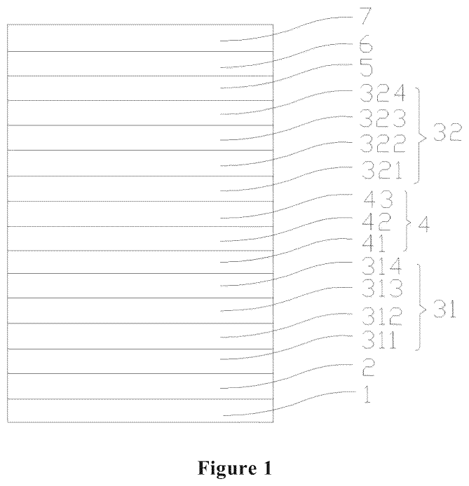

As described in Background, in existing technology, organic light-emitting diode (OLED) devices may have problems with high driving voltage, low efficiency and poor device stability. To solve the above problems, the present disclosure provides an organic light-emitting device. FIG. 1 illustrates a schematic structural diagram of an organic light-emitting device consistent with the disclosed embodiments of the present disclosure. As shown in FIG. 1, the organic light-emitting device includes a cascaded structure with an anode 1, two or more light-emitting units, and a cathode 6. The two adjacent light-emitting units are connected through a charge generation layer 4. The charge generation layer 4 includes an N-type charge generation layer 41, an intermediate layer 42 and a P-type charge generation layer 43, which are arranged in a stacked way.

The N-type charge generation layer 41 includes a first electron transport type organic material and an N-type dopant. The P-type charge generation layer 43 includes a first hole transport type organic material and a P-type dopant. The intermediate layer 42 has the property of transporting electrons and/or holes.

To reduce the device driving voltage, improve the device efficiency and improve the device stability, the present disclosure provides an organic light-emitting device. The charge generation layer 4 includes an N-type charge generation layer (NCGL) 41, an intermediate layer 42, and a P-type charge generation layer (PCGL) 43. By introducing the intermediate layer 42 between the NCGL and the PCGL, the N-type dopant and the P-type dopant may be prevented from diffusing with each other. As such, the N-type dopant and the P-type dopant may be prevented from directly contacting and reacting, and damaging the interface, and the interface stability may thus be improved. In addition, the intermediate layer 42 may have the capability of transmitting electrons and/or holes, the driving voltage of the device may be reduced, and the efficiency of the device may be improved.

In some embodiments, the intermediate layer 42 may include a first material. The first material may be a second electron transport type organic material and/or a second hole transport type organic material. Due to the difference in conductivity type, the host material used for the N-type doped layer may be different from the host material used for the P-type doped layer. Some organic materials may be used as the host material for the N-type doped organic layer, and may support the transport of electrons. Some organic materials may be used as the host material for the P-type doped organic layer, and may support the transport of holes. In a conventional OLED device, the electron transport type organic material may refer to a type of host material that may be used for N-type doped organic layers. For example, the electron transport type organic material may be a metal chelate oxine compound, such as tris(8-hydroxyquinoline) aluminum, or may be a triazine, a hydroxyquinoline derivative, an indole derivative or a silacyclopentene derivative. The hole transport type organic material may refer to a type of host material that may be used for the P-type doped organic layer. For example, the hole transport type organic material may be an aromatic tertiary amine having one or more trivalent nitrogen atom bonded only to a carbon atom, such as a monoaromatic amine, a diaromatic amine, a triaromatic amine or a polyaromatic amine. The middle layer 42 may be made of electron transport type organic material and/or hole transport type organic material. As such, the N-type dopant may be prevented from directly contacting and reacting with the P-type dopant, and damaging the interface, and the interface stability may thus be improved. In addition, the intermediate layer 42 may have electron transport or hole transport functions. Accordingly, the driving voltage of the device may be reduced and the efficiency of the device may be improved.

In some embodiments, the first material may include a second electron transport type organic material and a second hole transport type organic material. The N-type charge generation layer 41, the second electron transport type organic material, the second hole transport type organic material, and the P-type charge generation layer 43 are stacked in sequence. The middle layer 42 may be made of a first electron transport type organic material and a first hole transport type organic material stacked in sequence. As such, the middle layer 42 may not only have good electron transport or hole transport performance, but also reduce the driving voltage of the device and improves the device efficiency. In addition, the middle layer 42 may use same types of organic materials as the host material of the adjacent NCGL film layer and the host material of the adjacent PCGL film layer. As such, the interface stability may be improved.

To further reduce the driving voltage of the device and improve the efficiency of the device, in some embodiments, the first electron transport material and the second electron transport material may be made of a same material.

To further reduce the driving voltage of the device and improve the efficiency of the device, in some embodiments, the first hole transport type organic material and the second hole transport type organic material may be made of a same material.

In some embodiments, the intermediate layer 42 is a thin metal layer. The middle layer 42 may be made of a metal thin layer that has good electron transmission performance. As such, the driving voltage of the device may be reduced, and the efficiency of the device may be improved. The intermediate layer 42 may specifically be made of a material including Ti, Zr, Nb, Ta, Cr, Mo, W, Re, Fe, Ru, Os, Co, Rh, Ir, Ni, Pd, Pt, Cu, Ag, Au, Zn, Al, In, Sn, or an alloy thereof.

The thickness of the intermediate layer 42 may affect the driving voltage of the device, and may also affect the film-forming effect of the intermediate layer 42, and thus affect the stability of the device. To achieve a lower driving voltage and higher device stability, in some embodiments, the thickness of the intermediate layer 42 is in a range of approximately 5 to 200 Å.

In some embodiments, the thickness of the N-type charge generation layer 41 is in a range of approximately 50-200 Å, and the thickness of the P-type charge generation layer 43 is in a range of approximately 55-150 Å.

In a conventional OLED device, the N-type dopant used for the N-type charge generation layer may be an alkali metal, an alkali metal compound, an alkaline earth metal, or an alkaline earth metal compound, for example, Li, Na, K, Rb, Cs, Mg, Mg, Ca, Sr, Ba, La, Ce, Sm, Eu, Tb, Dy, Yb, or an inorganic or organic compound thereof. The N-type dopant of the N-type charge generation layer may also be an organic reducing agent with strong electron-donating properties, for example, bis(ethylenedisulfide)-tetrathiafulvalene, tetrathiafulvalene or a derivative thereof.

In some embodiments, the doping amount of the N-type dopant in the N-type charge generation layer 41 is in a range of approximately 1% to 6% by weight. As such, the generation of carriers in the charge generation layer may be improved.

In a conventional OLED device, the P-type dopant used in the P-type charge generation layer may be an oxidant with strong electron-withdrawing properties, for example, 2,3,5,6-tetrafluoro-7,7,8,8-tetracyanoquinone (F4-TCNQ), or other TCNQ derivatives, for example, inorganic oxidants such as iodine, FeC13, FeF3, SbC15, or some other metal halides.

In some embodiments, the doping amount of the P-type dopant in the P-type charge generation layer 43 is in a range of approximately 3% to 12% by weight. As such, the generation of carriers in the charge generation layer may be improved.

In some embodiments, the energy level difference between the HOMO energy level of the first hole transport type organic material and the LUMO energy level of the first electron transport type organic material is ≤0.8 ev. By controlling the difference between the HOMO energy level of the first hole transport type organic material as the host material of the N-type charge generation layer 41 and the LUMO energy level of the first electron transport type organic material as the host material of the P-type charge generation layer 43, the matching degree between the HOMO energy level of the first hole transport type organic material as the host material of the N-type charge generation layer 41 and the LUMO energy level of the first electron transport type organic material as the host material of the P-type charge generation layer 43 may be improved. As such, generation and migration of charges may have a better balance, a charge generation layer with a larger current under a certain voltage may be formed, and the driving voltage of the device may be reduced. Accordingly, the luminous brightness and current efficiency may be improved, the power loss may be reduced, and device efficiency may be improved.

In some embodiments, the light-emitting unit may also include an organic light-emitting layer and an electron transport layer. The electron transport layer may be disposed between the organic light-emitting layer and the N-type charge generation layer, or between the organic light-emitting layer and the cathode. The energy level difference between the LUMO energy level of the first electron transport type organic material and the LUMO energy level of the electron transport layer is ≤0.5 eV. By controlling the energy level difference between the LUMO energy level of the first hole transport type organic material of the host material of the N-type charge generation layer, and the LUMO energy level of the electron transport layer within the above range, injection of electrons into the electron transport layer after electron separation may be improved, and the device operating voltage may be reduced.

In some embodiments, the first electron transport type organic material may be selected from a structure shown in Formula I.

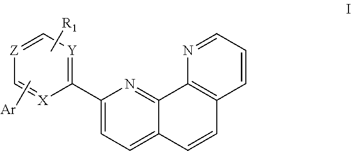

In Formula I, X, Y, and Z are independently selected from one of C and N, and one or more of X, Y, and Z is N. R1 is selected from one or more of H, phenyl, pyridyl, and pyridylphenyl. Ar is selected from substituted or unsubstituted phenyl, anthracenyl, phenanthrenyl, pyrenyl, triphenylenyl, pyridyl, o-phenanthroline, naphthoxazolyl, naphthoimidazolyl, naphthothiazolyl, where the substituent is one or more of —CN, phenyl, and o-phenanthroline. By taking the above-mentioned N-aromatic ring-connected phenanthroline as the host structure and limiting the substituents, a material with good electron transport performance may be obtained. By using the material obtained as the intermediate layer material, the balance between charge migration and injection may be improved, and a charge generation layer with large current may be formed under a certain voltage. As such, the driving voltage of the device may be reduced. Accordingly, while luminous brightness and current efficiency may be improved, power loss may be reduced, device efficiency may be improved, the diffusion of dopants may be blocked, and device stability may be improved.

Preferably, Ar may be selected from one or more substituted or unsubstituted phenyl group from —CN, phenyl and o-phenanthroline, one or more substituted or unsubstituted anthracenyl group from —CN, phenyl and o-phenanthroline, one or more substituted or unsubstituted phenanthrenyl group from —CN, phenyl and o-phenanthroline, one or more substituted or unsubstituted pyrenyl from —CN, phenyl and o-phenanthroline, one or more substituted or unsubstituted triphenylene from —CN, phenyl and o-phenanthroline, one or more substituted or unsubstituted pyridyl from —CN, phenyl and o-phenanthroline, —CN, phenyl, o-phenanthroline, one or more substituted or unsubstituted o-phenanthroline group from —CN, phenyl, o-phenanthroline, one or more substituted or unsubstituted naphthoxazolyl group from —CN, phenyl, o-phenanthroline, one or more substituted or unsubstituted naphthoimidazolyl from —CN, phenyl, o-phenanthroline, and one or more substituted or unsubstituted naphthothiazolyl from —CN, phenyl, o-phenanthroline.

More preferably, the first electron transport type organic material may be selected from one or more of the structures shown in Formulas (I-1) to (I-18).

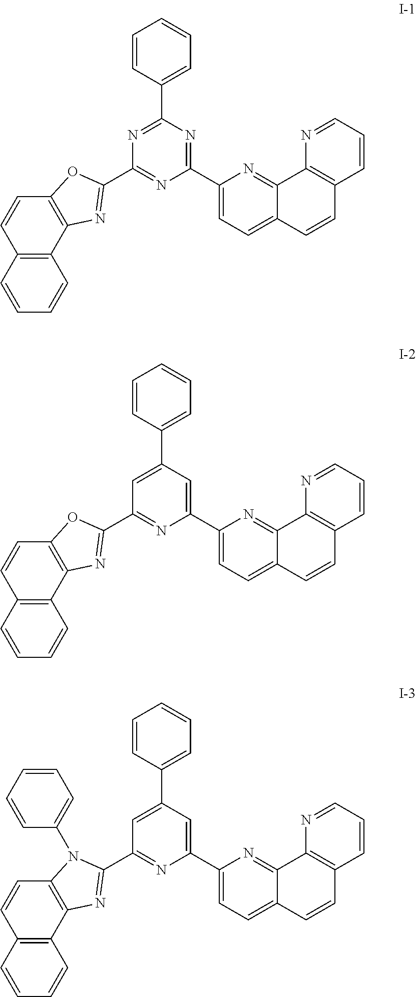 [SMILES: c1ccc(-c2nc(-c3ccc4ccc5cccnc5c4n3)nc(-c3nc4c(ccc5ccccc54)o3)n2)cc1 ; c1ccc(-c2cc(-c3ccc4ccc5cccnc5c4n3)nc(-c3nc4c(ccc5ccccc54)o3)c2)cc1 ; c1ccc(-c2cc(-c3ccc4ccc5cccnc5c4n3)nc(-c3nc4c5ccccc5ccc4n3-c3ccccc3)c2)cc1]

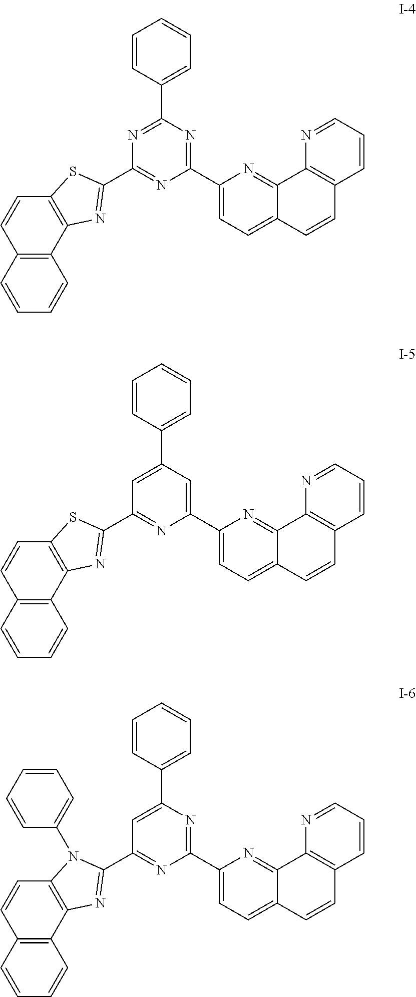 [SMILES: c1ccc(-c2nc(-c3ccc4ccc5cccnc5c4n3)nc(-c3nc4c(ccc5ccccc54)s3)n2)cc1 ; c1ccc(-c2cc(-c3ccc4ccc5cccnc5c4n3)nc(-c3nc4c(ccc5ccccc54)s3)c2)cc1 ; c1ccc(-c2cc(-c3nc4c5ccccc5ccc4n3-c3ccccc3)nc(-c3ccc4ccc5cccnc5c4n3)n2)cc1]

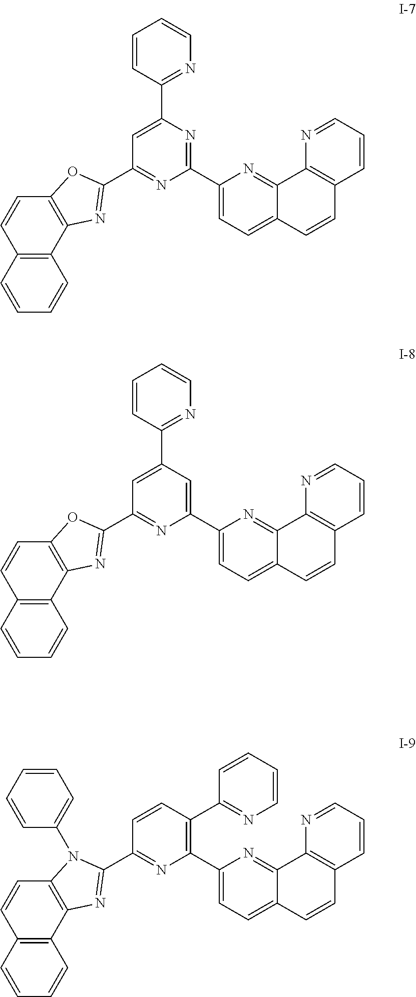 [SMILES: c1ccc(-c2cc(-c3nc4c(ccc5ccccc54)o3)nc(-c3ccc4ccc5cccnc5c4n3)n2)nc1 ; c1ccc(-c2cc(-c3ccc4ccc5cccnc5c4n3)nc(-c3nc4c(ccc5ccccc54)o3)c2)nc1 ; c1ccc(-n2c(-c3ccc(-c4ccccn4)c(-c4ccc5ccc6cccnc6c5n4)n3)nc3c4ccccc4ccc32)cc1]

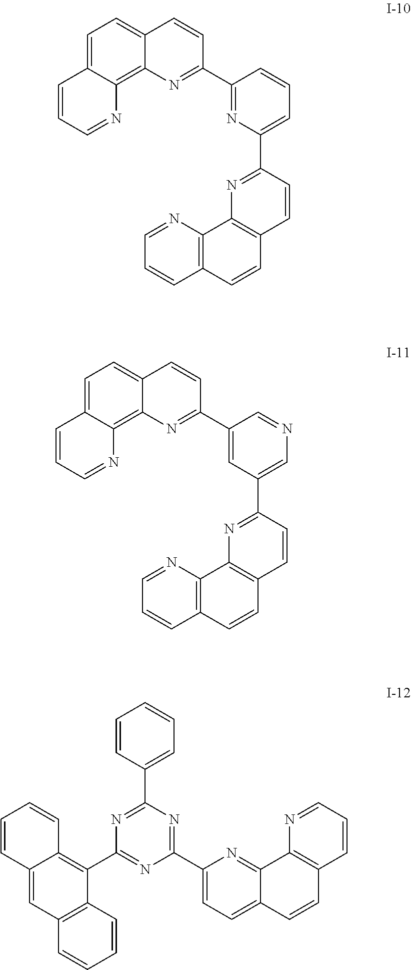 [SMILES: c1cc(-c2ccc3ccc4cccnc4c3n2)nc(-c2ccc3ccc4cccnc4c3n2)c1 ; c1cnc2c(c1)ccc1ccc(-c3cncc(-c4ccc5ccc6cccnc6c5n4)c3)nc12 ; c1ccc(-c2nc(-c3ccc4ccc5cccnc5c4n3)nc(-c3c4ccccc4cc4ccccc34)n2)cc1]

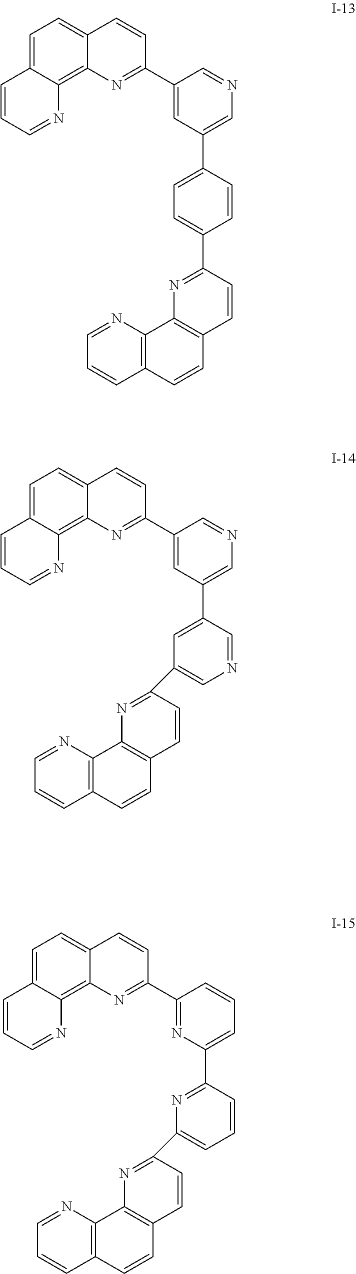 [SMILES: c1cnc2c(c1)ccc1ccc(-c3ccc(-c4cncc(-c5ccc6ccc7cccnc7c6n5)c4)cc3)nc12 ; c1cnc2c(c1)ccc1ccc(-c3cncc(-c4cncc(-c5ccc6ccc7cccnc7c6n5)c4)c3)nc12 ; c1cc(-c2cccc(-c3ccc4ccc5cccnc5c4n3)n2)nc(-c2ccc3ccc4cccnc4c3n2)c1]

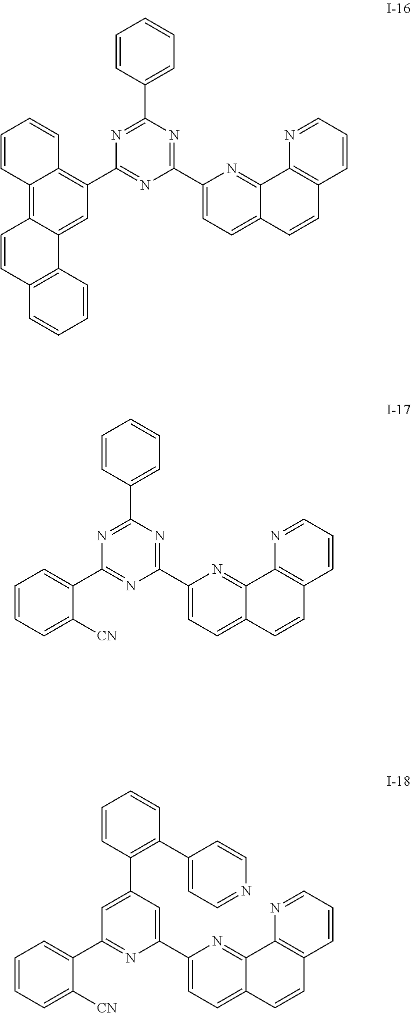 [SMILES: c1ccc(-c2nc(-c3ccc4ccc5cccnc5c4n3)nc(-c3cc4c5ccccc5ccc4c4ccccc34)n2)cc1 ; N#Cc1ccccc1-c1nc(-c2ccccc2)nc(-c2ccc3ccc4cccnc4c3n2)n1 ; N#Cc1ccccc1-c1cc(-c2ccccc2-c2ccncc2)cc(-c2ccc3ccc4cccnc4c3n2)n1]

In some embodiments, the first hole transport type organic material may be selected from one or more of the structures shown in Formulas (II-1) to (II-51).

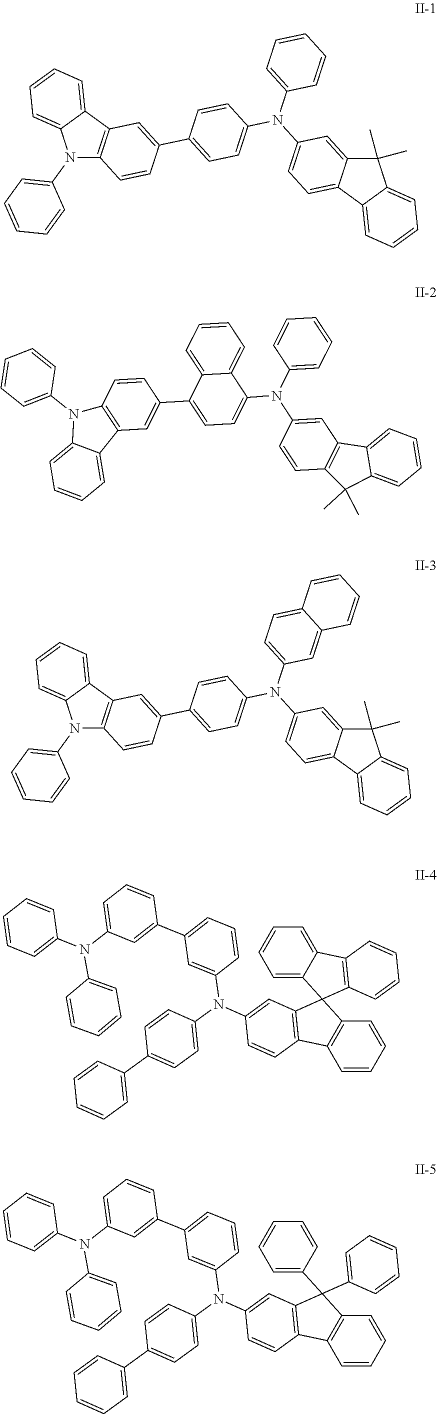 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2cc(N(c3ccccc3)c3ccc(-c4ccc5c(c4)c4ccccc4n5-c4ccccc4)c4ccccc34)ccc21 ; CC1(C)c2ccccc2-c2ccc(N(c3ccc(-c4ccc5c(c4)c4ccccc4n5-c4ccccc4)cc3)c3ccc4ccccc4c3)cc21 ; c1ccc(-c2ccc(N(c3cccc(-c4cccc(N(c5ccccc5)c5ccccc5)c4)c3)c3ccc4c(c3)C3(c5ccccc5-c5ccccc53)c3ccccc3-4)cc2)cc1 ; c1ccc(-c2ccc(N(c3cccc(-c4cccc(N(c5ccccc5)c5ccccc5)c4)c3)c3ccc4c(c3)C(c3ccccc3)(c3ccccc3)c3ccccc3-4)cc2)cc1]

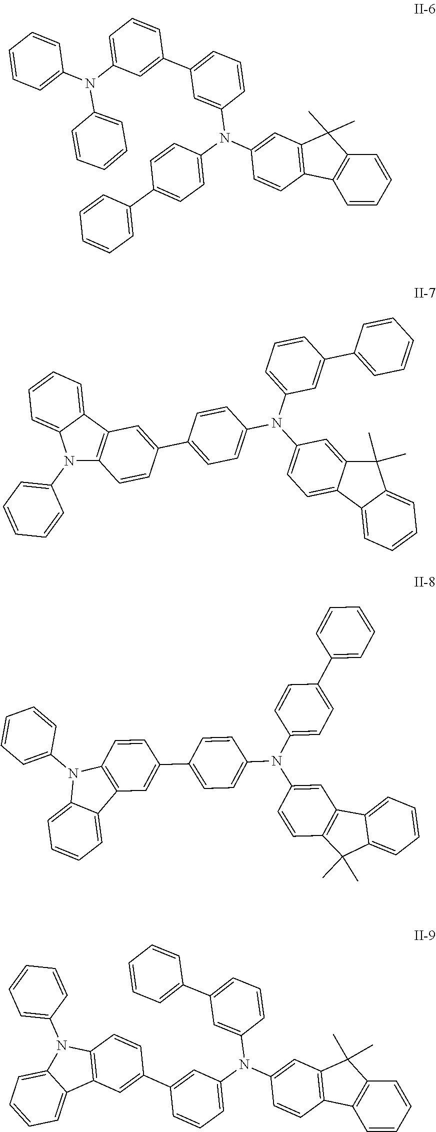 [SMILES: CC1(C)c2ccccc2-c2ccc(N(c3ccc(-c4ccccc4)cc3)c3cccc(-c4cccc(N(c5ccccc5)c5ccccc5)c4)c3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2cc(N(c3ccc(-c4ccccc4)cc3)c3ccc(-c4ccc5c(c4)c4ccccc4n5-c4ccccc4)cc3)ccc21 ; CC1(C)c2ccccc2-c2ccc(N(c3cccc(-c4ccccc4)c3)c3cccc(-c4ccc5c(c4)c4ccccc4n5-c4ccccc4)c3)cc21]

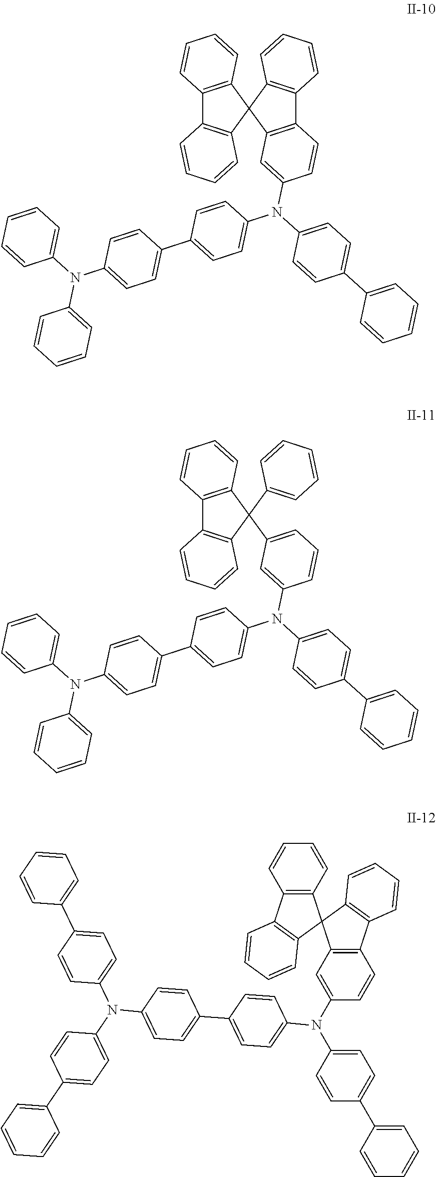 [SMILES: c1ccc(-c2ccc(N(c3ccc(-c4ccc(N(c5ccccc5)c5ccccc5)cc4)cc3)c3ccc4c(c3)C3(c5ccccc5-c5ccccc53)c3ccccc3-4)cc2)cc1 ; c1ccc(-c2ccc(N(c3ccc(-c4ccc(N(c5ccccc5)c5ccccc5)cc4)cc3)c3cccc(C4(c5ccccc5)c5ccccc5-c5ccccc54)c3)cc2)cc1 ; c1ccc(-c2ccc(N(c3ccc(-c4ccccc4)cc3)c3ccc(-c4ccc(N(c5ccc(-c6ccccc6)cc5)c5ccc6c(c5)C5(c7ccccc7-c7ccccc75)c5ccccc5-6)cc4)cc3)cc2)cc1]

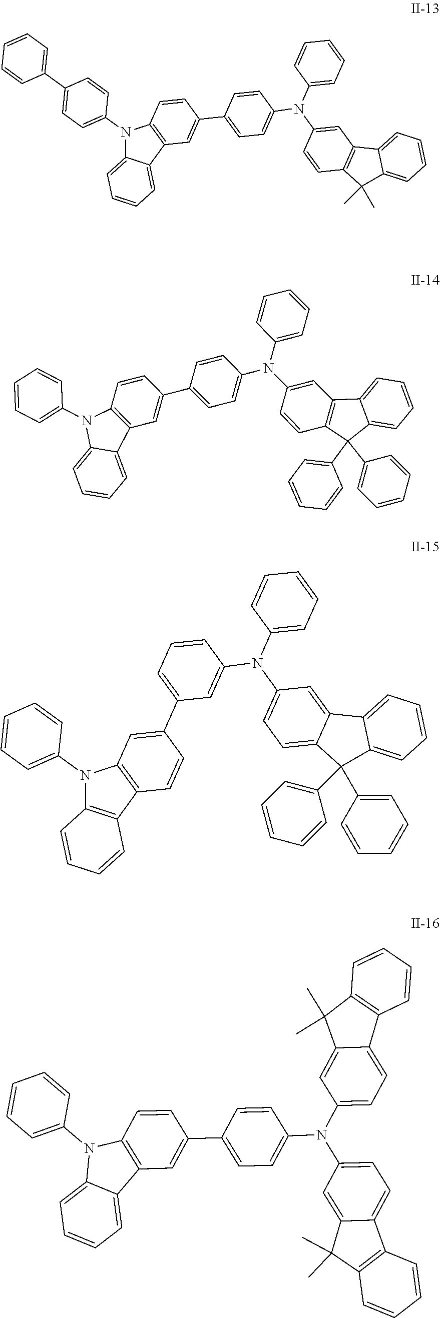 [SMILES: CC1(C)c2ccccc2-c2cc(N(c3ccccc3)c3ccc(-c4ccc5c(c4)c4ccccc4n5-c4ccc(-c5ccccc5)cc4)cc3)ccc21 ; c1ccc(N(c2ccc(-c3ccc4c(c3)c3ccccc3n4-c3ccccc3)cc2)c2ccc3c(c2)-c2ccccc2C3(c2ccccc2)c2ccccc2)cc1 ; c1ccc(N(c2cccc(-c3ccc4c5ccccc5n(-c5ccccc5)c4c3)c2)c2ccc3c(c2)-c2ccccc2C3(c2ccccc2)c2ccccc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

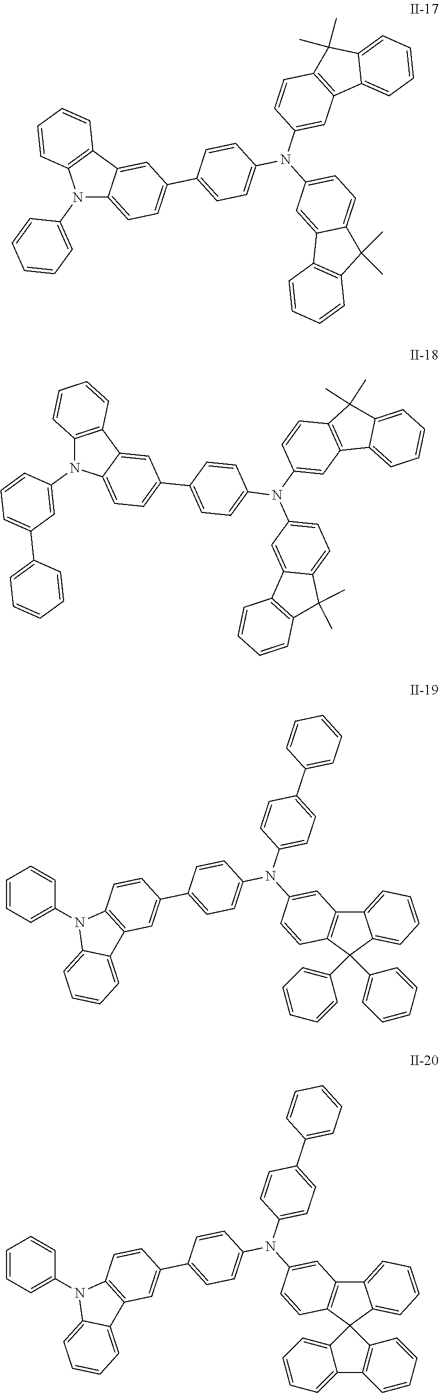 [SMILES: CC1(C)c2ccccc2-c2cc(N(c3ccc(-c4ccc5c(c4)c4ccccc4n5-c4ccccc4)cc3)c3ccc4c(c3)-c3ccccc3C4(C)C)ccc21 ; CC1(C)c2ccccc2-c2cc(N(c3ccc(-c4ccc5c(c4)c4ccccc4n5-c4cccc(-c5ccccc5)c4)cc3)c3ccc4c(c3)-c3ccccc3C4(C)C)ccc21 ; c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(-c2ccc(N(c3ccc(-c4ccc5c(c4)c4ccccc4n5-c4ccccc4)cc3)c3ccc4c(c3)-c3ccccc3C43c4ccccc4-c4ccccc43)cc2)cc1]

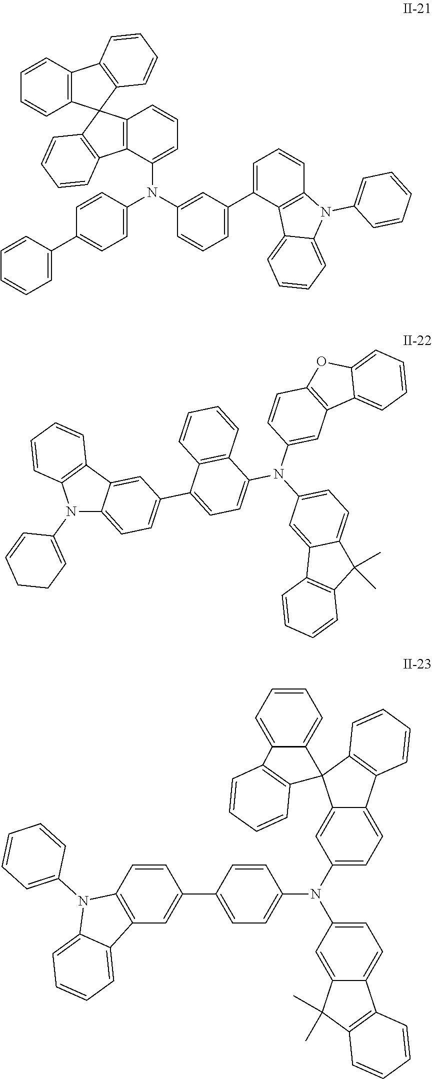 [SMILES: c1ccc(-c2ccc(N(c3cccc(-c4cccc5c4c4ccccc4n5-c4ccccc4)c3)c3cccc4c3-c3ccccc3C43c4ccccc4-c4ccccc43)cc2)cc1 ; CC1(C)c2ccccc2-c2cc(N(c3ccc4oc5ccccc5c4c3)c3ccc(-c4ccc5c(c4)c4ccccc4n5C4=CCCC=C4)c4ccccc34)ccc21 ; CC1(C)c2ccccc2-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc21]

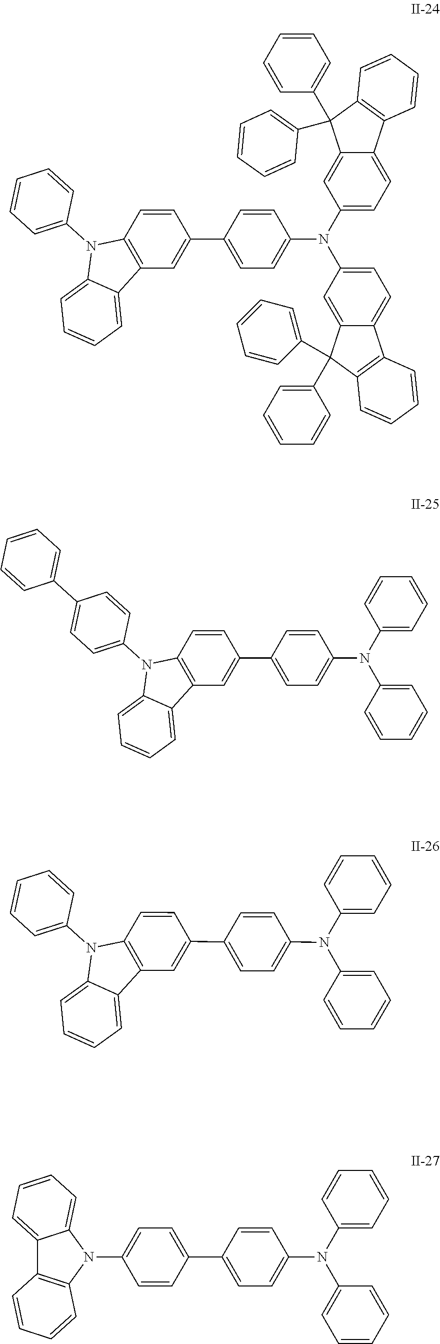 [SMILES: c1ccc(-n2c3ccccc3c3cc(-c4ccc(N(c5ccc6c(c5)C(c5ccccc5)(c5ccccc5)c5ccccc5-6)c5ccc6c(c5)C(c5ccccc5)(c5ccccc5)c5ccccc5-6)cc4)ccc32)cc1 ; c1ccc(-c2ccc(-n3c4ccccc4c4cc(-c5ccc(N(c6ccccc6)c6ccccc6)cc5)ccc43)cc2)cc1 ; c1ccc(N(c2ccccc2)c2ccc(-c3ccc4c(c3)c3ccccc3n4-c3ccccc3)cc2)cc1 ; c1ccc(N(c2ccccc2)c2ccc(-c3ccc(-n4c5ccccc5c5ccccc54)cc3)cc2)cc1]

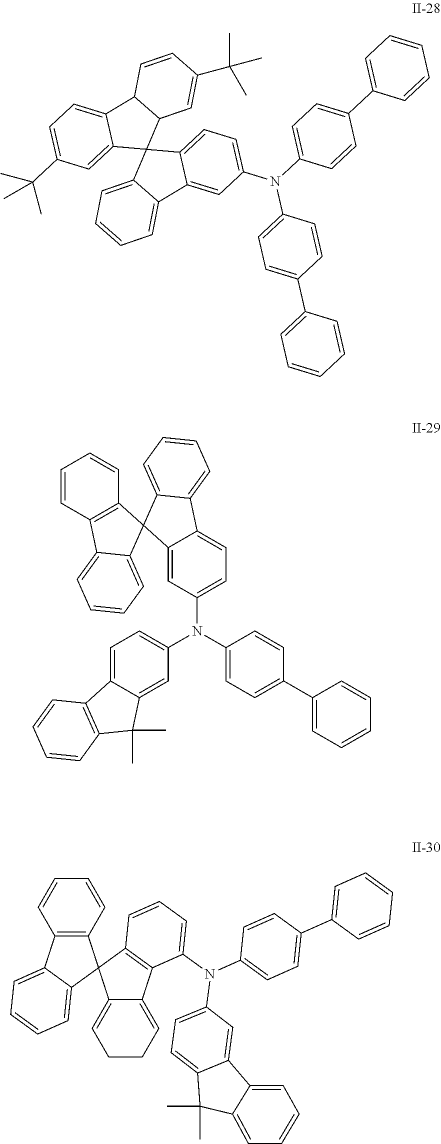 [SMILES: CC(C)(C)C1=CC2C(C=C1)c1ccc(C(C)(C)C)cc1C21c2ccccc2-c2cc(N(c3ccc(-c4ccccc4)cc3)c3ccc(-c4ccccc4)cc3)ccc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2cc(N(c3ccc(-c4ccccc4)cc3)c3cccc4c3C3=CCCC=C3C43c4ccccc4-c4ccccc43)ccc21]

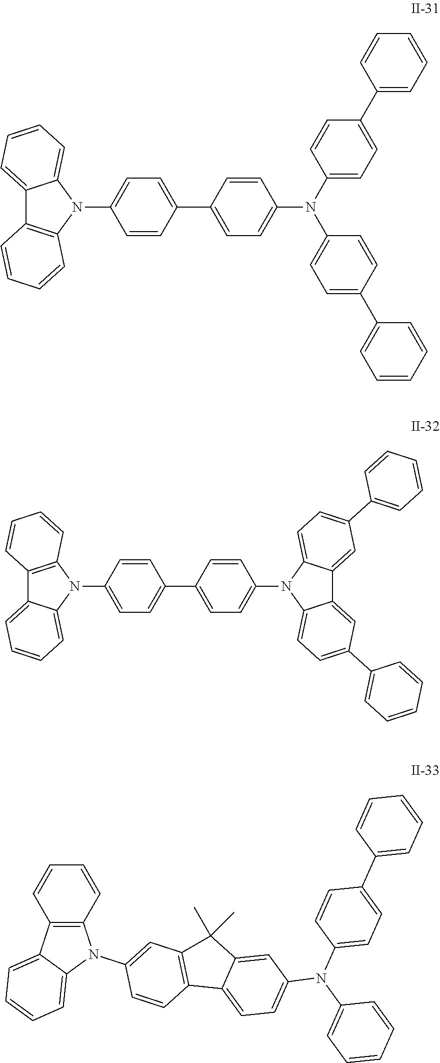 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; c1ccc(-c2ccc3c(c2)c2cc(-c4ccccc4)ccc2n3-c2ccc(-c3ccc(-n4c5ccccc5c5ccccc54)cc3)cc2)cc1 ; CC1(C)c2cc(N(c3ccccc3)c3ccc(-c4ccccc4)cc3)ccc2-c2ccc(-n3c4ccccc4c4ccccc43)cc21]

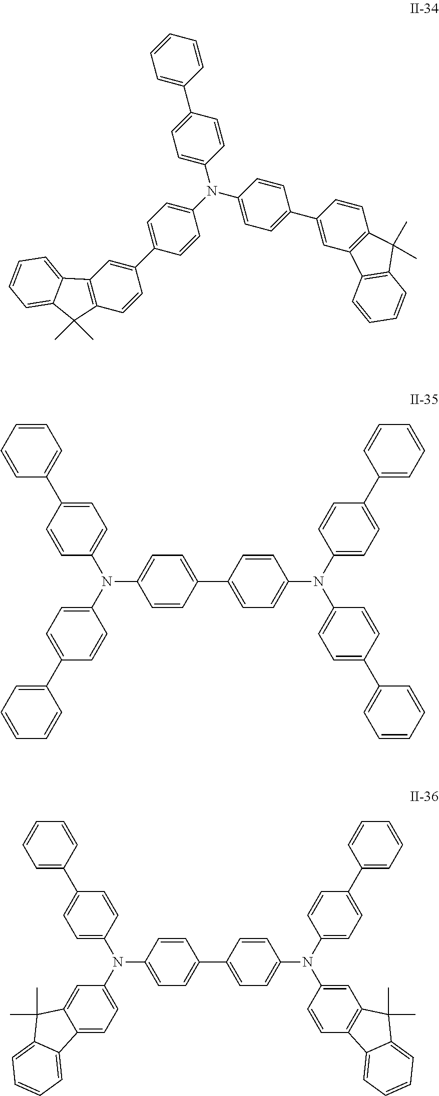

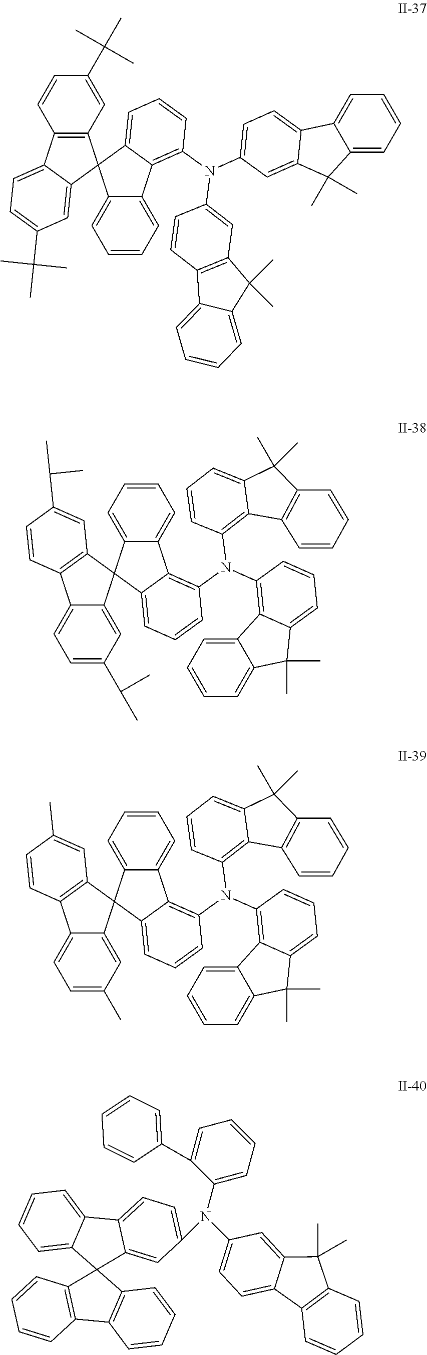 [SMILES: CC(C)(C)c1ccc2c(c1)C1(c3cc(C(C)(C)C)ccc3-2)c2ccccc2-c2c(N(c3ccc4c(c3)C(C)(C)c3ccccc3-4)c3ccc4c(c3)C(C)(C)c3ccccc3-4)cccc21 ; CC(C)c1ccc2c(c1)C1(c3cc(C(C)C)ccc3-2)c2ccccc2-c2c(N(c3cccc4c3-c3ccccc3C4(C)C)c3cccc4c3-c3ccccc3C4(C)C)cccc21 ; Cc1ccc2c(c1)C1(c3cc(C)ccc3-2)c2ccccc2-c2c(N(c3cccc4c3-c3ccccc3C4(C)C)c3cccc4c3-c3ccccc3C4(C)C)cccc21 ; CC1(C)c2ccccc2-c2ccc(N(c3ccc4c(c3)C3(c5ccccc5-c5ccccc53)c3ccccc3-4)c3ccccc3-c3ccccc3)cc21]

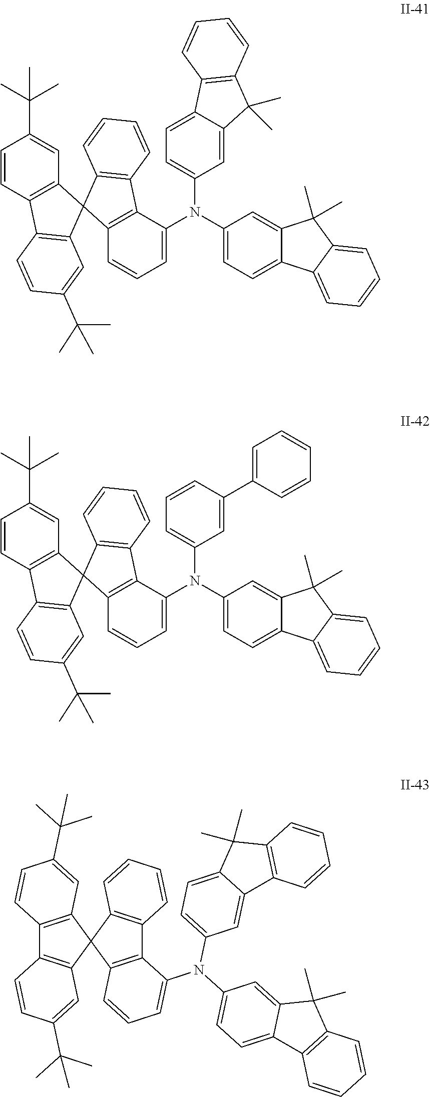 [SMILES: CC(C)(C)c1ccc2c(c1)C1(c3cc(C(C)(C)C)ccc3-2)c2ccccc2-c2c(N(c3ccc4c(c3)C(C)(C)c3ccccc3-4)c3ccc4c(c3)C(C)(C)c3ccccc3-4)cccc21 ; CC(C)(C)c1ccc2c(c1)C1(c3cc(C(C)(C)C)ccc3-2)c2ccccc2-c2c(N(c3cccc(-c4ccccc4)c3)c3ccc4c(c3)C(C)(C)c3ccccc3-4)cccc21 ; CC(C)(C)c1ccc2c(c1)C1(c3cc(C(C)(C)C)ccc3-2)c2ccccc2-c2c(N(c3ccc4c(c3)-c3ccccc3C4(C)C)c3ccc4c(c3)C(C)(C)c3ccccc3-4)cccc21]

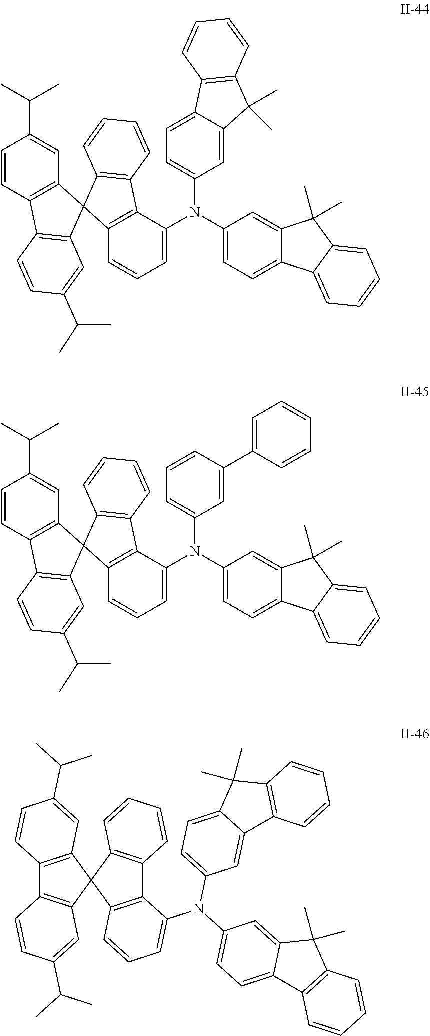 [SMILES: CC(C)c1ccc2c(c1)C1(c3cc(C(C)C)ccc3-2)c2ccccc2-c2c(N(c3ccc4c(c3)C(C)(C)c3ccccc3-4)c3ccc4c(c3)C(C)(C)c3ccccc3-4)cccc21 ; CC(C)c1ccc2c(c1)C1(c3cc(C(C)C)ccc3-2)c2ccccc2-c2c(N(c3cccc(-c4ccccc4)c3)c3ccc4c(c3)C(C)(C)c3ccccc3-4)cccc21 ; CC(C)c1ccc2c(c1)C1(c3cc(C(C)C)ccc3-2)c2ccccc2-c2c(N(c3ccc4c(c3)-c3ccccc3C4(C)C)c3ccc4c(c3)C(C)(C)c3ccccc3-4)cccc21]

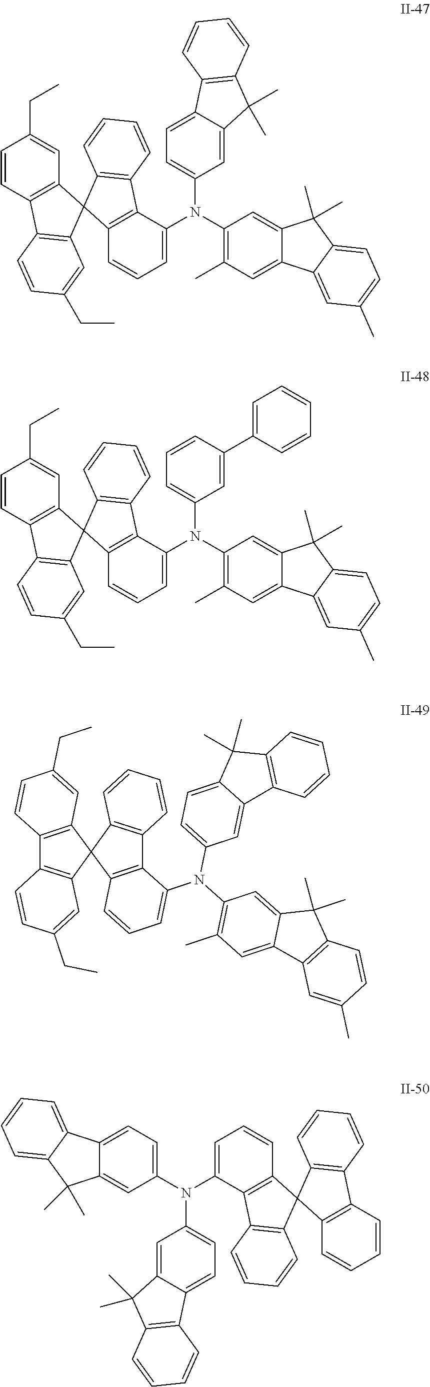 [SMILES: CCc1ccc2c(c1)C1(c3cc(CC)ccc3-2)c2ccccc2-c2c(N(c3ccc4c(c3)C(C)(C)c3ccccc3-4)c3cc4c(cc3C)-c3cc(C)ccc3C4(C)C)cccc21 ; CCc1ccc2c(c1)C1(c3cc(CC)ccc3-2)c2ccccc2-c2c(N(c3cccc(-c4ccccc4)c3)c3cc4c(cc3C)-c3cc(C)ccc3C4(C)C)cccc21 ; CCc1ccc2c(c1)C1(c3cc(CC)ccc3-2)c2ccccc2-c2c(N(c3ccc4c(c3)-c3ccccc3C4(C)C)c3cc4c(cc3C)-c3cc(C)ccc3C4(C)C)cccc21 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

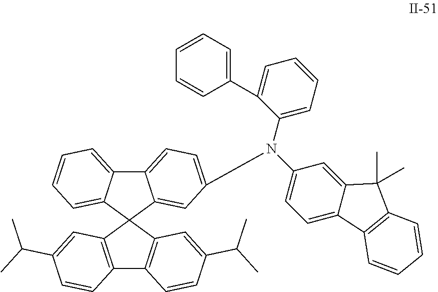 [SMILES: CC(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)C)ccc1-2]

Devices such as vehicle-mounted devices that have high requirements for component lifespans may have strict requirements for low energy consumption and low voltage for OLEDs. Specifically, in some embodiments, a hole blocking layer is disposed between the organic light-emitting layer and the electron transport layer. The difference between the LUMO energy level of the hole blocking layer and the LUMO energy level of the electron transport layer is greater than approximately 0.5 eV and not greater than approximately 1.0 eV. The large LUMO energy level difference between the hole blocking layer material and the electron transport layer may control the electron injection into the light-emitting layer, and construct a multi-hole system of the light-emitting layer (EML) to improve the high-temperature stability and the lifespan of the device. This approach may be used for devices such as vehicle-mounted devices that have high requirements for lifespans.

Preferably, the electron mobility of the hole blocking layer may be smaller than the electron mobility of the electron transport layer. With the lower electron mobility of the hole blocking layer and the higher electron mobility of the transport layer, the electron injection into the light-emitting layer may be controlled, and the high-temperature stability and lifespan of the device may be improved.

Preferably, the electron mobility of the hole blocking layer is in a range of approximately 1.0⁻⁹ to 1.0⁻⁸ cm²/Vs. The low mobility of the hole blocking layer may improve the high temperature stability and lifespan of the device.

Preferably, the hole blocking layer includes a triazine-based bipolar electron transport material having one or more of a triarylamine group, a carbazole group, and a phenoloxazine group. The triazine bipolar electron transport material including the above-mentioned HB material with shallow LUMO and slow transmission may control the electron injection into the light-emitting layer.

Preferably, the triazine bipolar electron transport material may be selected from one or more of the structures shown in Formula III and Formula IV.

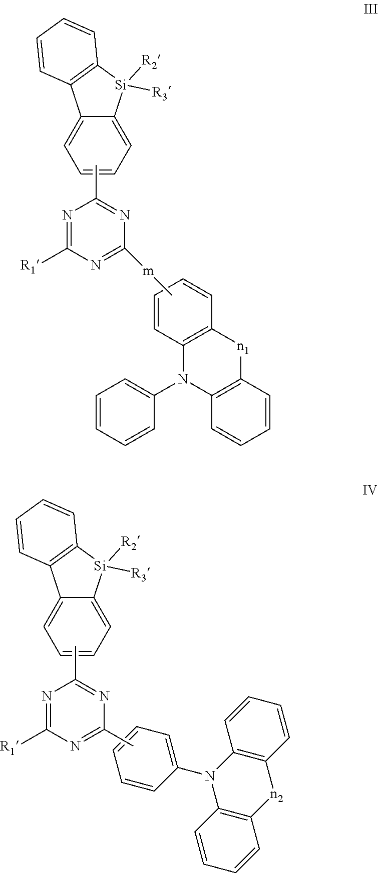

In Formula III and Formula IV, R₁′ is selected from one of the substituted or unsubstituted phenyl, naphthyl, and dibenzofuran, and the substituent is an aromatic group selected from one of phenyl, biphenyl, and dibenzofuran; R₂′ and R₃′ are independently selected from one of alkyl and phenyl, or R₂′ and R₃′ are independently selected from one of alkylene and phenylene, and R₂′, R₃′, and Si connected to R₂′ and R₃′ together form a five-membered ring; m is selected from a single bond or a phenylene group; and n₁ is one of a single bond, an S atom or an O atom.

In Formula III and Formula IV, R₄′ is selected from one of the substituted or unsubstituted phenyl, naphthyl, and dibenzofuran, the substituent is an aromatic group, and the aromatic group is selected from one of phenyl, biphenyl, and dibenzofuran; R₅′ and R₆′ are independently selected from one of alkyl and phenyl, or R₅′ and R₆′ are independently selected from one of alkylene and phenylene, and R₅′, R₆′, and Si connected to R₅′ and R₆′ together form a five-membered ring; and n₂ is selected from a single bond, an S atom or an O atom.

Preferably, the triazine bipolar electron transport material may be selected from one or more of the structures shown in Formulas (V-1) to (V-10).

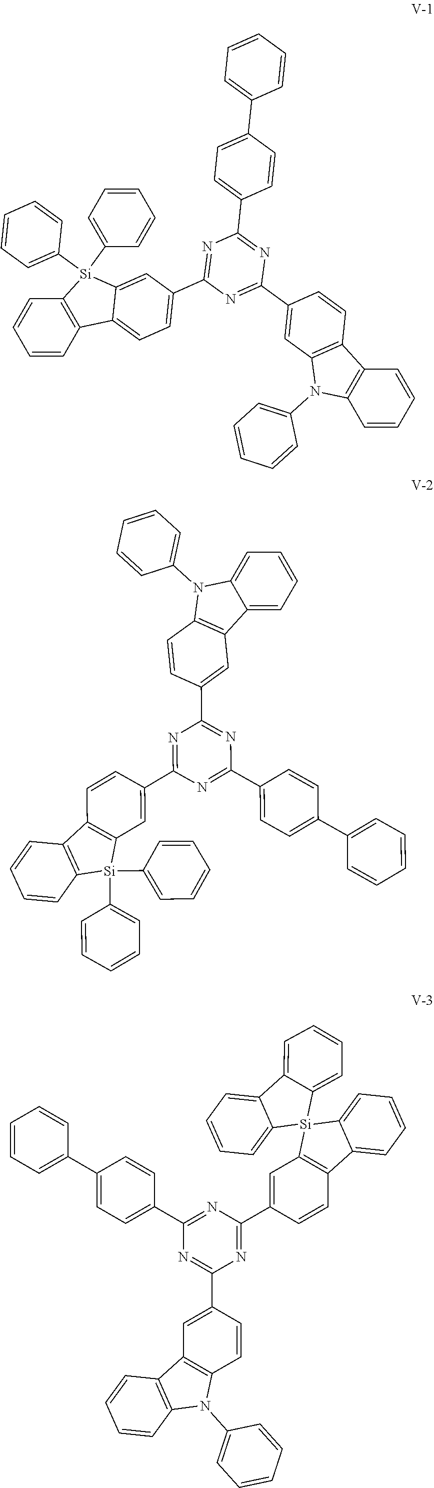 [SMILES: c1ccc(-c2ccc(-c3nc(-c4ccc5c(c4)[Si](c4ccccc4)(c4ccccc4)c4ccccc4-5)nc(-c4ccc5c6ccccc6n(-c6ccccc6)c5c4)n3)cc2)cc1 ; c1ccc(-c2ccc(-c3nc(-c4ccc5c(c4)[Si](c4ccccc4)(c4ccccc4)c4ccccc4-5)nc(-c4ccc5c(c4)c4ccccc4n5-c4ccccc4)n3)cc2)cc1 ; c1ccc(-c2ccc(-c3nc(-c4ccc5c(c4)[Si]4(c6ccccc6-c6ccccc64)c4ccccc4-5)nc(-c4ccc5c(c4)c4ccccc4n5-c4ccccc4)n3)cc2)cc1]

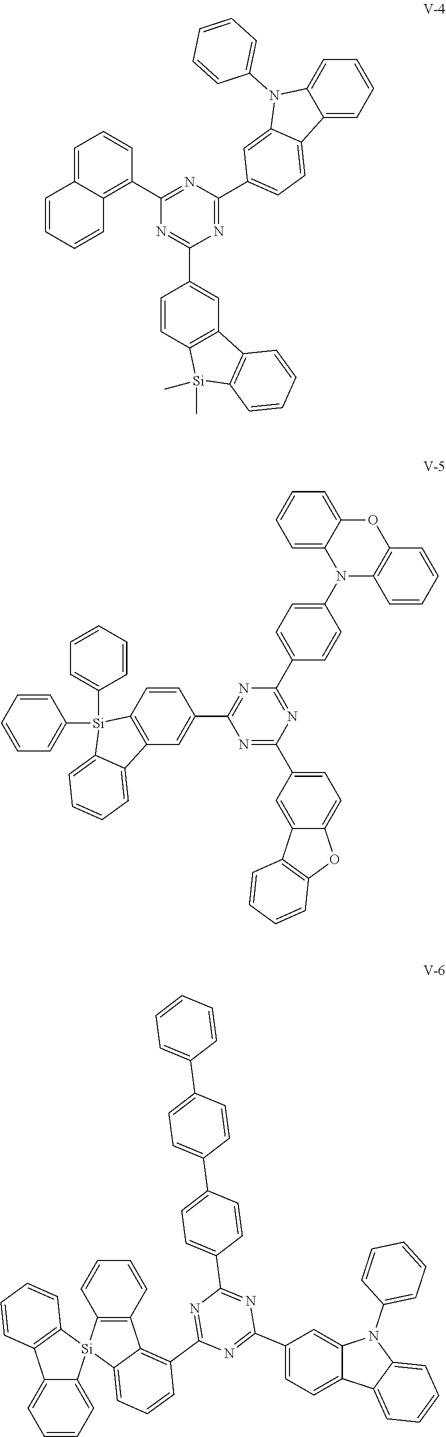 [SMILES: C[Si]1(C)c2ccccc2-c2cc(-c3nc(-c4ccc5c6ccccc6n(-c6ccccc6)c5c4)nc(-c4cccc5ccccc45)n3)ccc21 ; c1ccc([Si]2(c3ccccc3)c3ccccc3-c3cc(-c4nc(-c5ccc(N6c7ccccc7Oc7ccccc76)cc5)nc(-c5ccc6oc7ccccc7c6c5)n4)ccc32)cc1 ; c1ccc(-c2ccc(-c3ccc(-c4nc(-c5ccc6c7ccccc7n(-c7ccccc7)c6c5)nc(-c5cccc6c5-c5ccccc5[Si]65c6ccccc6-c6ccccc65)n4)cc3)cc2)cc1]

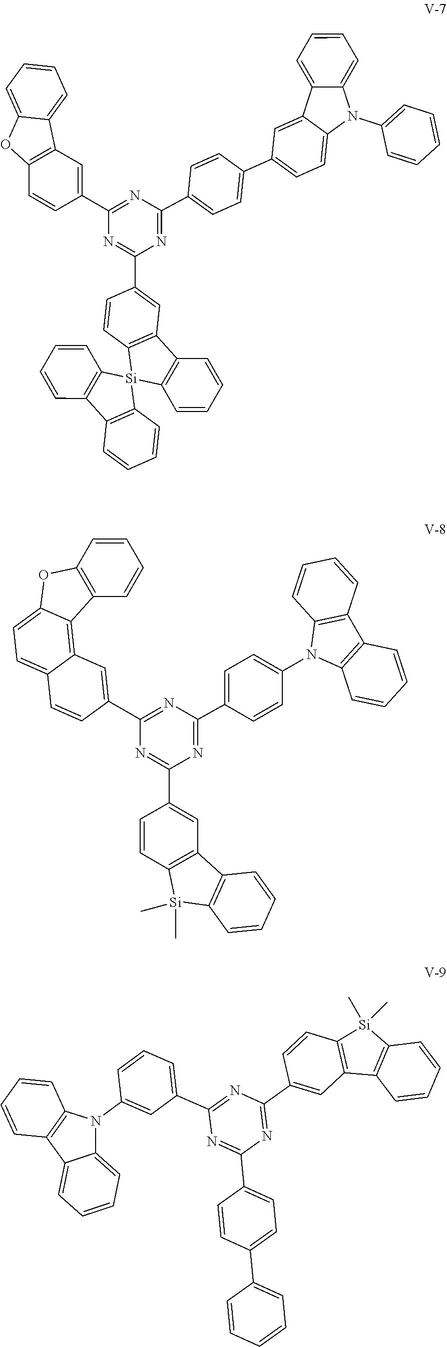 [SMILES: c1ccc(-n2c3ccccc3c3cc(-c4ccc(-c5nc(-c6ccc7c(c6)-c6ccccc6[Si]76c7ccccc7-c7ccccc76)nc(-c6ccc7oc8ccccc8c7c6)n5)cc4)ccc32)cc1 ; C[Si]1(C)c2ccccc2-c2cc(-c3nc(-c4ccc(-n5c6ccccc6c6ccccc65)cc4)nc(-c4ccc5ccc6oc7ccccc7c6c5c4)n3)ccc21 ; C[Si]1(C)c2ccccc2-c2cc(-c3nc(-c4ccc(-c5ccccc5)cc4)nc(-c4cccc(-n5c6ccccc6c6ccccc65)c4)n3)ccc21]

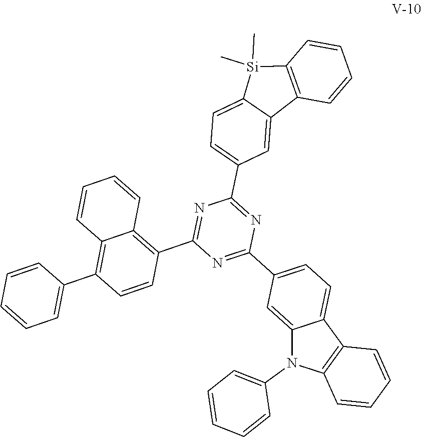 [SMILES: C[Si]1(C)c2ccccc2-c2cc(-c3nc(-c4ccc5c6ccccc6n(-c6ccccc6)c5c4)nc(-c4ccc(-c5ccccc5)c5ccccc45)n3)ccc21]

By using the above triazine bipolar electron transport material, the electron injection into the light-emitting layer may be controlled, and a suitable LUMO energy level may be obtained. In addition, the triazine bipolar electron transport material may meet the energy level matching requirements with common electron transport layer materials on the market, and a good matching degree may be obtained.

Devices such as mobile phones and tablets that have high requirements for reducing energy consumption may have strict requirements for low energy consumption and low voltage for OLEDs. Specifically, in some embodiments, a hole blocking layer may be disposed between the organic light-emitting layer and the electron transport layer. The difference between the LUMO energy level of the hole blocking layer and the LUMO energy level of the electron transport layer is ≤0.4 eV. By taking advantage of the smaller LUMO difference between the hole blocking layer material and the electron transport layer material, an EML multi-electron system may be constructed to reduce the voltage of the device and improve efficiency. Accordingly, the energy consumption of the devices such as mobile phones and tablets that have high requirements for low energy consumption may be reduced.

Preferably, the electron mobility of the hole blocking layer is in a range of approximately 1.0⁻⁷ to 1.0⁻⁶ cm²/Vs. The high mobility of the hole blocking layer may accelerate the injection of electrons into the light-emitting layer. Accordingly, the voltage of the device may be reduced, and the efficiency may be improved.

Preferably, the hole blocking layer includes a triazine-based strong electron transport material. The triazine-based strong electron transport material may have a structure shown in Formula VI.

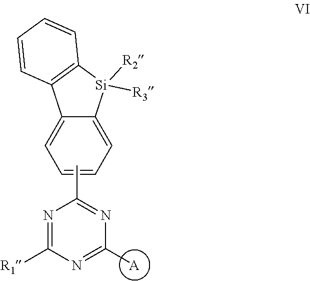

In Formula VI, A may be selected from one of substituted or unsubstituted phenyl, biphenyl, naphthyl, anthracenyl, phenanthrenyl, triphenylene, azaphenanthrenyl, 9,9-dimethylacridinyl, dibenzofuranyl, and dibenzothiophenyl, and the substituted substituent is one or more of phenyl, naphthyl, pyridyl, pyridylphenyl, and quinolyl; and R1″ may be selected from substituted or unsubstituted dibenzofuranyl and dibenzothiophenyl, where the substituted substituent is one or more of an alkyl, a phenyl, and a phenylene group. R2″ and R3″ may be independently selected from one of alkyl and phenyl; or R2″ and R3″ may be independently selected from one of alkylene and phenyl, and R2″, R3″ and Si connected to R2″ and R3″ may together form a five-membered ring. The hole blocking material may include a triazine-type strong electron transport material having the structure shown in Formula VI and with a deep LUMO and fast transmission. Accordingly, the electron injection luminescence may be accelerated, the voltage of the device may be reduced, and the efficiency may be improved.

Preferably, the triazine strong electron transport material may be selected from one or more of the structures shown in Formulas (VII-1) to (V11-10).

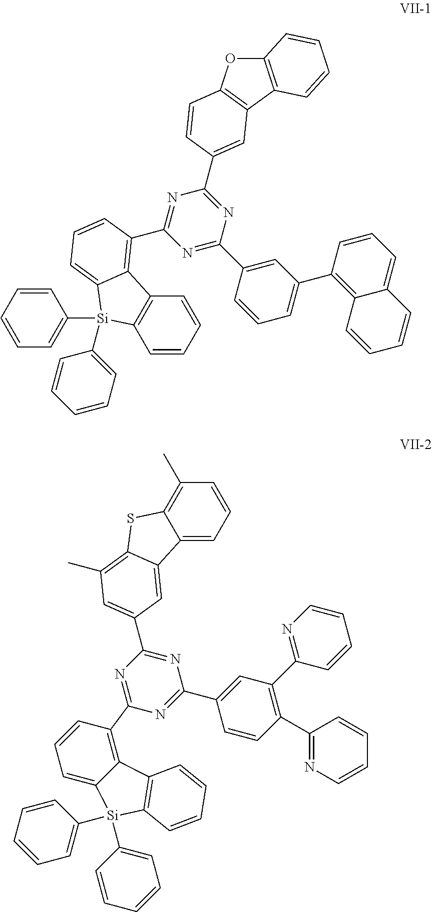 [SMILES: c1ccc([Si]2(c3ccccc3)c3ccccc3-c3c(-c4nc(-c5cccc(-c6cccc7ccccc67)c5)nc(-c5ccc6oc7ccccc7c6c5)n4)cccc32)cc1 ; Cc1cccc2c1sc1c(C)cc(-c3nc(-c4ccc(-c5ccccn5)c(-c5ccccn5)c4)nc(-c4cccc5c4-c4ccccc4[Si]5(c4ccccc4)c4ccccc4)n3)cc12]

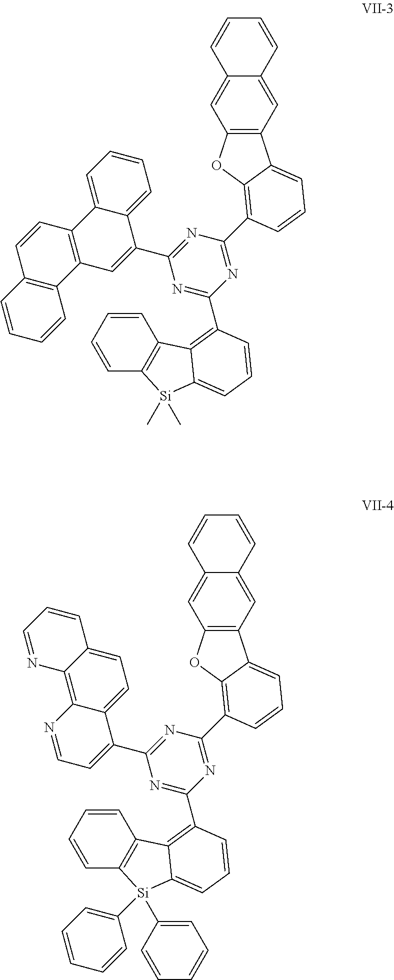 [SMILES: C[Si]1(C)c2ccccc2-c2c(-c3nc(-c4cc5c6ccccc6ccc5c5ccccc45)nc(-c4cccc5c4oc4cc6ccccc6cc45)n3)cccc21 ; c1ccc([Si]2(c3ccccc3)c3ccccc3-c3c(-c4nc(-c5ccnc6c5ccc5cccnc56)nc(-c5cccc6c5oc5cc7ccccc7cc56)n4)cccc32)cc1]

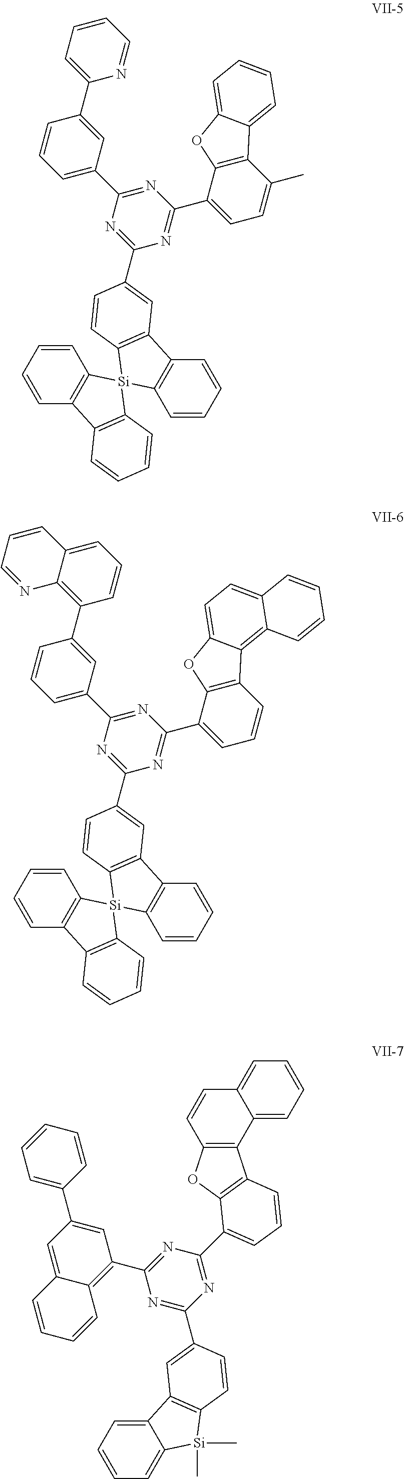 [SMILES: Cc1ccc(-c2nc(-c3cccc(-c4ccccn4)c3)nc(-c3ccc4c(c3)-c3ccccc3[Si]43c4ccccc4-c4ccccc43)n2)c2oc3ccccc3c12 ; c1cc(-c2nc(-c3ccc4c(c3)-c3ccccc3[Si]43c4ccccc4-c4ccccc43)nc(-c3cccc4c3oc3ccc5ccccc5c34)n2)cc(-c2cccc3cccnc23)c1 ; C[Si]1(C)c2ccccc2-c2cc(-c3nc(-c4cc(-c5ccccc5)cc5ccccc45)nc(-c4cccc5c4oc4ccc6ccccc6c45)n3)ccc21]

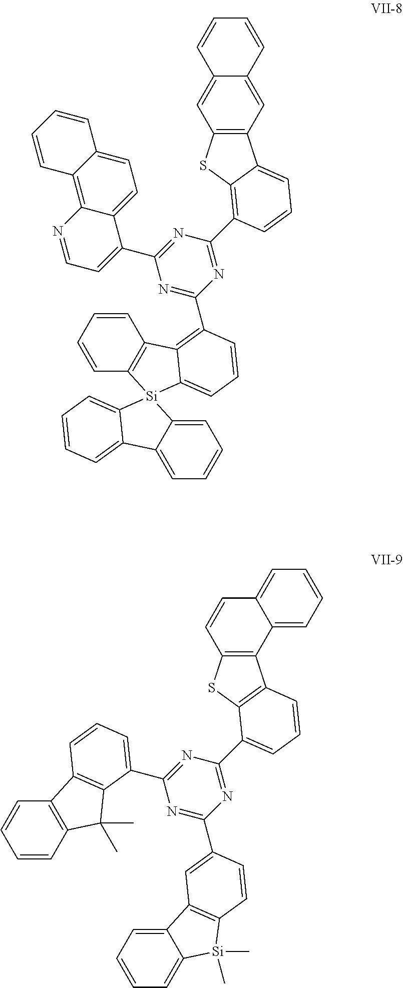 [SMILES: c1ccc2c(c1)-c1ccccc1[Si]21c2ccccc2-c2c(-c3nc(-c4ccnc5c4ccc4ccccc45)nc(-c4cccc5c4sc4cc6ccccc6cc45)n3)cccc21 ; CC1(C)c2ccccc2-c2cccc(-c3nc(-c4ccc5c(c4)-c4ccccc4[Si]5(C)C)nc(-c4cccc5c4sc4ccc6ccccc6c45)n3)c21]

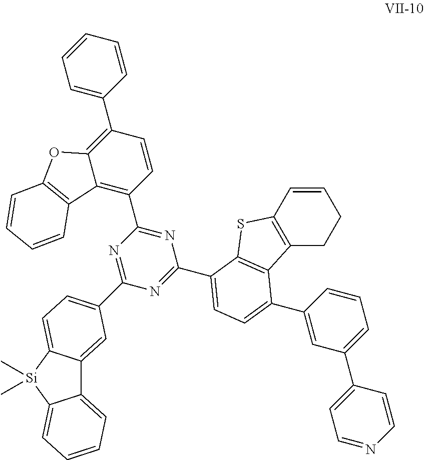 [SMILES: C[Si]1(C)c2ccccc2-c2cc(-c3nc(-c4ccc(-c5cccc(-c6ccncc6)c5)c5c6c(sc45)C=CCC6)nc(-c4ccc(-c5ccccc5)c5oc6ccccc6c45)n3)ccc21]

The above triazine strong electron transport material may have good electron transport properties and a suitable LUMO energy level, and may meet the energy level matching requirements with common electron transport layer materials on the market. As such, good matching between the above triazine strong electron transport material and common electron transport layer materials on the market may be achieved.

In some embodiments, the electron transport layer material may be selected from one or more of 2,8-bis(diphenylphosphinyl) dibenzothiophene (PPT), 1,3,5-tri(1-phenyl-1H-benzimidazol-2-yl)benzene (TPBi), 2,8-bis(diphenylphosphinyl) dibenzofuran (PPF), bis(2-diphenylphosphinyl) diphenyl ether (DPEPO), lithium fluoride (LiF), 4,6-bis(3,5-di(3-pyridyl)phenyl)-2-methylpyrimidine (B3PYMPM), 4,7-diphenyl-1,10-phenanthroline (Bphen), 1,3,5-tris[(3-pyridyl)-3-phenyl]benzene (TmPyBP), 1,3,5-tris(p-pyridyl-3-phenyl)benzene (TpPyPB), tris[2,4,6-trimethyl-3-(3-pyridyl)phenyl] borane (3TPYMB), 1,3-bis(3,5-dipyridyl-3-phenyl)benzene (B3PYPB), 1,3-bis[3,5-di(pyridyl-3-yl)phenyl]benzene (BMPYPHB), 2,4,6-tris(biphenyl-3-yl)-1,3,5-triazine (T2T), diphenylbis[4-(pyridin-3-yl)phenyl]silane (DPPS), bis(2-methyl-8-hydroxyquinolinolato-N1,O8)-(1,1′-biphenyl-4-hydroxy)aluminum (BAlq), 8-hydroxyquinolinolato-lithium (Liq), tris(8-hydroxyquinolinolato)aluminum (Alq3), 2-biphenyl-4-yl-5-(4-tert-butylphenyl)-1,3,4-oxadiazole (PBD), spiro-PBD, 2,9-bis(2-methyl-8-hydroxyquinolinolato-N1,O8)-(1,1′-biphenyl-4-hydroxy)aluminum (BAlq), 8-hydroxyquinolinolato-lithium (Liq), tris(8-hydroxyquinolinolato)aluminum (Alq3), 2-biphenyl-4-yl-5-(4-tert-butylphenyl)-1,3,4-oxadiazole (PBD), spiro-PBD, (Naphthalene-2-yl)-4,7-diphenyl-1,10-phenanthroline (NBphen), 2,9-dimethyl-4,7-diphenyl-1,10-phenanthroline (BCP), 3-(4-biphenyl)-4-phenyl-5-tert-butylphenyl-1,2,4-triazole (TAZ), 4-(naphthalene-1-yl)-3,5-diphenyl-4H-1,2,4-triazole (NTAZ), 2,4,6-tris(3′-(pyridin-3-yl)biphenyl-3-yl)-1,3,5-triazine (TmPPPyTz), poly[9,9-bis(3′-(N,N-dimethyl)-N-ethylammonium)-propyl)-2,7-fluorene]-alternate-2,7-(9,9-dioctylfluorene)] (PFNBr), tris(phenylquinoxaline) (TPQ), TSPO1, and 2-[4-(9,10-di-2-naphthalene-2-yl-2-anthracen-2-yl)phenyl]-1-phenyl-1H-benzimidazole (ZADN). The present disclosure is not limited to the above materials.

In some embodiments, the N-type dopant may be selected from alkali metals, alkaline earth metals, rare earth metals, or compounds thereof, for example, lithium (Li), sodium (Na), potassium (K), rubidium (Rb), cesium (Cs), magnesium (Mg), calcium (Ca), ytterbium (Yb), Cs2CO3, etc.

In some embodiments, the P-type dopant may be selected from one or more of the structures shown in Formulas (VIII-1)-(VIII-14). The present disclosure is not limited to the structures shown in Formulas (VIII-1)-(VIII-14).

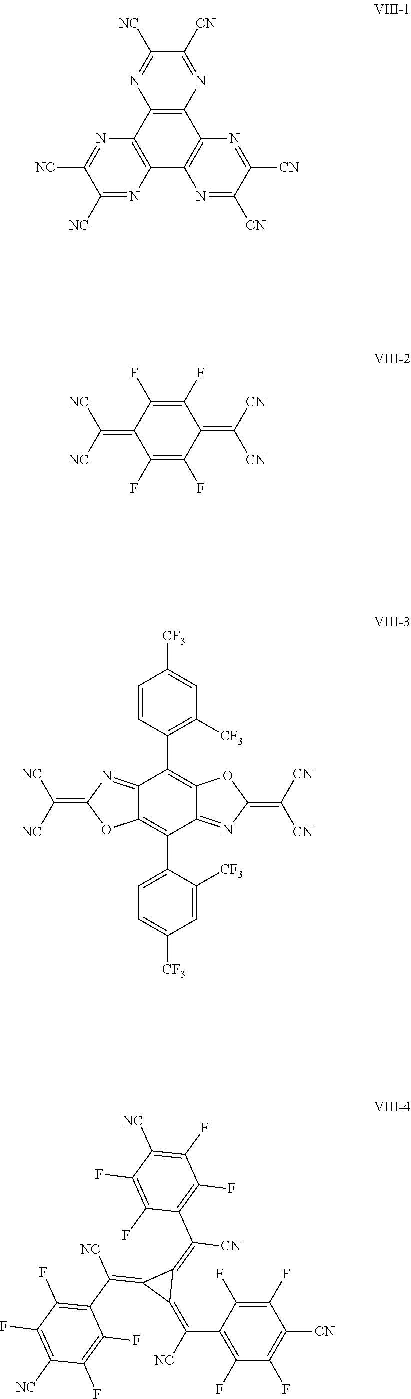 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

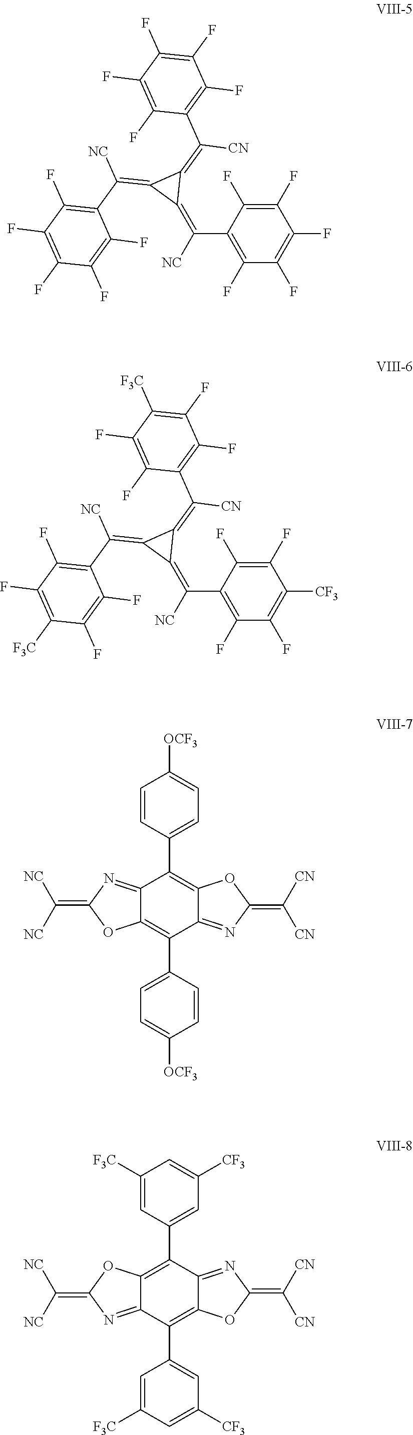 [SMILES: N#CC(=C1C(=C(C#N)c2c(F)c(F)c(F)c(F)c2F)C1=C(C#N)c1c(F)c(F)c(F)c(F)c1F)c1c(F)c(F)c(F)c(F)c1F ; N#CC(=C1C(=C(C#N)c2c(F)c(F)c(C(F)(F)F)c(F)c2F)C1=C(C#N)c1c(F)c(F)c(C(F)(F)F)c(F)c1F)c1c(F)c(F)c(C(F)(F)F)c(F)c1F ; N#CC(C#N)=c1nc2c(-c3ccc(OC(F)(F)F)cc3)c3oc(=C(C#N)C#N)nc3c(-c3ccc(OC(F)(F)F)cc3)c2o1 ; N#CC(C#N)=c1nc2c(-c3cc(C(F)(F)F)cc(C(F)(F)F)c3)c3oc(=C(C#N)C#N)nc3c(-c3cc(C(F)(F)F)cc(C(F)(F)F)c3)c2o1]

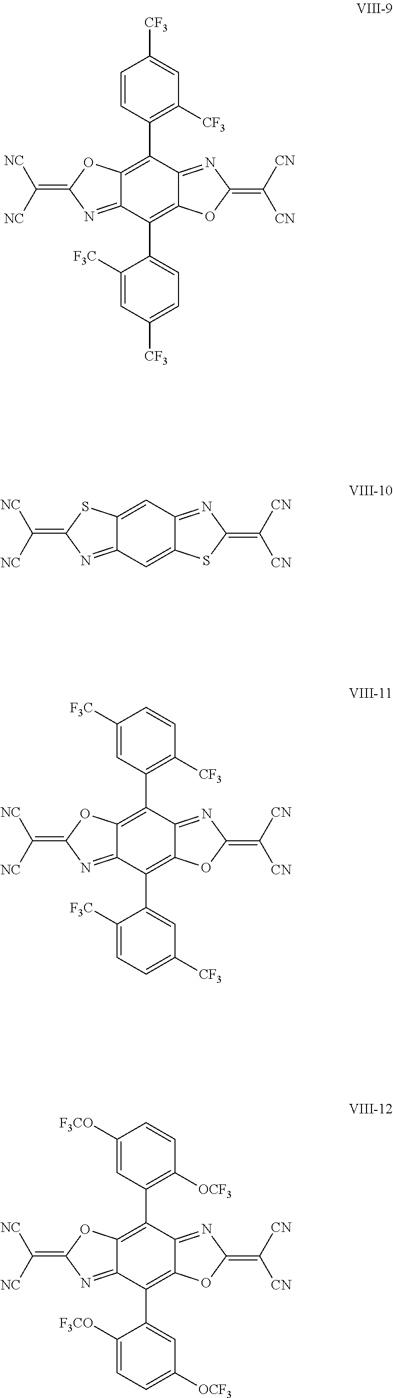 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(C#N)=c1nc2cc3sc(=C(C#N)C#N)nc3cc2s1 ; N#CC(C#N)=c1nc2c(-c3cc(C(F)(F)F)ccc3C(F)(F)F)c3oc(=C(C#N)C#N)nc3c(-c3cc(C(F)(F)F)ccc3C(F)(F)F)c2o1 ; N#CC(C#N)=c1nc2c(-c3cc(OC(F)(F)F)ccc3OC(F)(F)F)c3oc(=C(C#N)C#N)nc3c(-c3cc(OC(F)(F)F)ccc3OC(F)(F)F)c2o1]

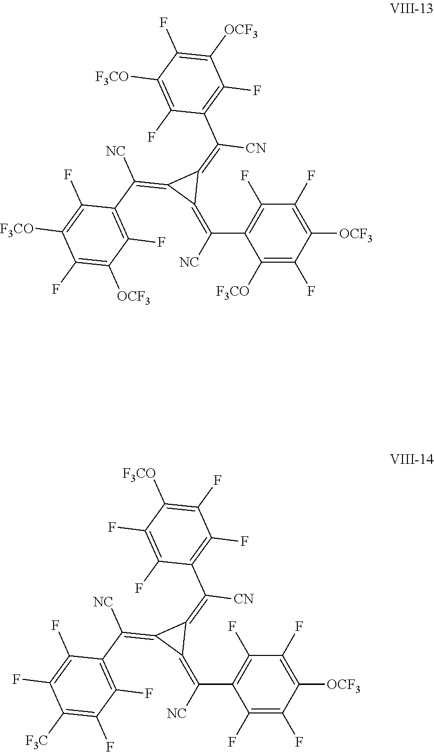 [SMILES: N#C/C(=C1/C(=C(\C#N)c2c(F)c(F)c(OC(F)(F)F)c(F)c2OC(F)(F)F)/C1=C(\C#N)c1c(F)c(OC(F)(F)F)c(F)c(OC(F)(F)F)c1F)c1c(F)c(OC(F)(F)F)c(F)c(OC(F)(F)F)c1F ; N#C/C(=C1/C(=C(\C#N)c2c(F)c(F)c(C(F)(F)F)c(F)c2F)/C1=C(\C#N)c1c(F)c(F)c(OC(F)(F)F)c(F)c1F)c1c(F)c(F)c(OC(F)(F)F)c(F)c1F]

In some embodiments, a cap layer 7 may be disposed on the upper surface of the cathode 6. The cap layer 7 covers the cathode 6 to reduce light loss of the device.

In some embodiments, the material of the anode 1 may be selected from metals such as copper, gold, silver, iron, chromium, nickel, manganese, palladium, platinum or alloys thereof, or may be selected from metal oxides such as indium oxide, zinc oxide, indium tin oxide (ITO), indium zinc oxide (IZO), etc. The material of the anode 1 may also be selected from conductive polymers such as polyaniline, polypyrrole, poly(3-methylthiophene), etc. In addition, the material of the anode 1 may also be selected from other materials suitable for hole injections, including conventional anode materials and combinations thereof.

In some embodiments, the material of the cathode may be selected from metals such as aluminum, magnesium, silver, calcium, indium, tin, titanium, etc. or alloys thereof, or may be selected from multilayer metal materials such as LiF/Al, LiO2/Al, BaF2/Al, etc. In addition, the material of the cathode may also be selected from materials suitable for electron injections, including conventional cathode materials and combinations thereof.

In some embodiments, the organic light-emitting device may also include a hole injection layer 2 and an electron injection layer 5. Each light-emitting unit includes a hole transport layer, a light-emitting layer, a hole blocking layer and an electron transport layer that are arranged in a stacked way.

In some embodiments, the hole injection layer 2 and the hole transport layer may independently include one or more of 4,4′4″-tris(3-methylphenylamino)triphenylamine (MTDATA), 4,4′,4″-tris(N,N-diphenylamino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2TNATA), copper phthalocyanine (CuPc), 1,3,5-tris[4-(diphenylamino)phenyl]benzene (TDAPB), 2,2′-dimethyl-N,N′-di-1-naphthyl-N,N′-diphenyl[1,1′-biphenyl]-4,4′-diamine (α-NPD), 4,4′,4″-tri(carbazole-9-yl)triphenylamine (TCTA), 1,3-dicarbazole-9-ylbenzene (mCP), 4,4′-di(9-carbazole)biphenyl (CBP), 3,3′-di(N-carbazolyl)-1,1′-biphenyl (mCBP), 2,3,6,7,10,11-hexacyano-1,4,5,8,9,12-hexaazatriphenylene (HATCN), 4,4′-cyclohexylbis[N,N-di(4-methylphenyl)aniline (TAPC), N,N′-diphenyl-N,N′-(1-naphthyl)-1,1′-biphenyl-4,4′-diamine (α-NPB), N,N′-di(naphthalene-2-yl)-N,N′-di(phenyl)biphenyl-4,4′-diamine (NPB), poly(3,4-ethylenedioxythiophene)-polystyrenesulfonic acid (PEDOT:PSS), 2,3,5,6-tetrafluoro-7,7,8,8-tetracyanoquinodimethane (F4TCNQ), N-(biphenyl-4-yl)-9,9-dimethyl-N-(4-(9-phenyl-9H-carbazol-3-yl)phenyl)-9H-fluorene-2-amine polyvinylcarbazole (PVK), 4,4′-bis(N-carbazolyl)-1,1′-biphenyl (CBP), poly[N,N′-bis(4-butylphenyl)-N,N′-bis(phenyl)-benzidine] (poly-TPD), poly[(9,9-dioctylfluorenyl-2,7-diyl)-co-(4,4′-(N-(4-sec-butylphenyl)diphenylamine))] (TFB), 1,1-bis[4-(N,N′-di(p-tolyl)amino)phenyl)cyclohexane (TAPC), 3,5-bis(9H-carbazole-9-yl)-N,N-diphenylaniline (DCDPA), N-(biphenyl-4-yl)-9,9-dimethyl-N-(4-(9-phenyl-9H-carbazole-3-yl)phenyl)-9H-fluorene-2-amine, N-(biphenyl-4-yl)-N-(4-(9-phenyl-9H-carbazole-3-yl)phenyl) biphenyl-4-amine, N-([1,1′-biphenyl]-4-yl)-9,9-dimethyl-N-(4-(9-phenyl-9H-carbazole-3-yl)phenyl)-9H-fluorene-2-amine, N4, N4, N4′, N4′-tetrakis([1,1′-biphenyl]-4-yl)-[1,1′-biphenyl]-4,4′-diamine)-9-phenyl-3,9-bicarbazole (CCP), and molybdenum trioxide (MoO3). The present disclosure is not limited to the above materials.

In some embodiments, the electron injection layer 5 may include one or more of Yb, Li, Cs, and Cs₂CO₃. The present disclosure is not limited to the above materials.

In some embodiments, the light-emitting layer includes a host material and a dopant material. The host material includes a red light host material, a green light host material, and a blue light host material. The dopant material includes a red light dopant, a green light dopant, and a blue light dopant. Specifically, the doping material may be selected from one or more of fluorescent materials, phosphorescent materials, thermally activated delayed fluorescent materials, and induced luminescent materials. Specially, the host material may be selected from one or more of 2,8-bis(diphenylphosphinyl)dibenzothiophene, 4,4′-bis(9-carbazole)biphenyl, 3,3′-bis(N-carbazolyl)-1,1′-biphenyl, 2,8-bis(diphenylphosphino)dibenzofuran, bis(4-(9H-carbazolyl-9-yl)phenyl)diphenylsilane, 9-(4-tert-butylphenyl)-3,6-bis(triphenylsilyl)-9H-carbazole, bis(2-diphenylphosphinyl)diphenyl ether, 1,3-bis[3,5-di(pyridin-3-yl)phenyl]benzene, 4,6-bis(3,5-di(3-pyridin-3-yl)phenyl)-2-methylpyrimidine, 9-(3-(9H-carbazolyl-9-yl)phenyl)-9H-carbazole-3-cyano, 9-phenyl-9-[4-(triphenylsilyl)phenyl]-9H-fluorene, 1,3,5-tri(1-phenyl-1H-benzimidazol-2-yl)benzene, diphenyl[4-(triphenylsilyl)phenyl]phosphine oxide, 4,4′,4″-tri(carbazolyl-9-yl)triphenylamine, 2,6-dicarbazole-1,5-pyridine, polyvinylcarbazole and polyfluorene. The present disclosure is not limited to the above materials.

The present disclosure also provides a display panel, including an organic light-emitting device provided by the present disclosure. The implementation principle and beneficial effects of the display panel are similar to the implementation principle and beneficial effects of the organic light-emitting device, and will not be repeated herein.

In some embodiments, the display panel may be a flexible panel, a curved panel, etc.

The present disclosure also provides a display apparatus, including a display panel provided by the present disclosure. The implementation principle and beneficial effects of the display apparatus are similar to the implementation principle and beneficial effects of the display panel, and will not be repeated herein.

Specific embodiments will be given below, which should not be construed as limiting the scope of protection of the present disclosure.

### Embodiment 1

A tandem OLED device includes an anode 1, two or more light-emitting units (a first light-emitting unit 31 and a second light-emitting unit 32) and a cathode 6 that are stacked one over another. The two light-emitting units are connected through a charge generation layer 4. Specifically, the tandem OLED device includes the following structures arranged in sequence from bottom to top: the anode 1, a hole injection layer 2, a first hole transport layer 311, a first light-emitting layer 312, a first hole blocking layer 313, a first electron transport layer 314, an N-type charge generation layer 41, an intermediate layer 42, a P-type charge generation layer 43, a second hole transport layer 321, a second light-emitting layer 322, a second hole blocking layer 323, a second electron transport layer 324, an electron injection layer 5, the cathode 6 (magnesium silver electrode), and a cap layer 7.

A method for preparing the tandem OLED device includes operations S1-S16.

S1, cutting a glass substrate into a piece of approximately 50 mm×approximately 50 mm×approximately 0.7 mm in size, ultrasonically treating the glass substrate in isopropanol and deionized water for approximately 30 minutes respectively, then exposing the glass substrate to ozone for cleaning for approximately 10 minutes, followed by mounting the glass substrate with ITO disposed by magnetron sputtering, as the anode, on a vacuum deposition device.

S2, fabricating the hole injection layer: vacuum evaporating a compound of PCGL and PD on the ITO anode layer at a vacuum degree of approximately 2×10-6 Pa. PCGL is used as the host material, PD is used as the doping material, and the mass ratio of PCGL to PD is approximately 96:4. The compound has a thickness of approximately 10 nm. The compound is used as the hole injection layer.

S3, fabricating the first hole transport layer: vacuum evaporating compound PCGL on the hole injection layer as the first hole transport layer with a thickness of approximately 20 nm.

S4, vacuum evaporating the first light-emitting layer on the first hole transport layer. The organic compound BH is used as a host material, BD is used as a doping material, and the mass ratio of BH to BD is approximately 98:2. The thickness of the first light-emitting layer is approximately 20 nm.

S5, fabricating the first hole blocking layer: vacuum evaporating compound HB on the first light-emitting layer as the first hole blocking layer with a thickness of approximately 5 nm.

S6, vacuum evaporating compounds ET and Alq3 on the first hole blocking layer as a first electron transport layer, with a mass ratio of ET to Alq3 of approximately 1:1 and a thickness of approximately 10 nm.

S7, vacuum evaporating the N-type charge generation layer on the first electron transport layer. The host material is NCGL I-1, the N-type dopant is Yb, and the mass ratio of NCGL to Yb is approximately 96:4. The N-type charge generation layer has a thickness of approximately 165 Å.

S8, vacuum evaporating an NCGL I-1 layer on the N-type charge generation layer. The NCGL I-1 layer has a thickness of approximately 15 Å, and may operate as the intermediate layer.

S9, vacuum evaporating a P-type charge generation layer on the intermediate layer. The host material is PCGL, the P-type dopant is PD, and the mass ratio of PCGL to PD is approximately 90:10. The P-type charge generation layer has a thickness of approximately 100 Å.

S10, vacuum evaporating compound PCGL on the P-type charge generation layer as the second hole transport layer with a thickness of 40 nm.

S11, vacuum evaporating the second light-emitting layer on the second hole transport layer. The compound BH is used as a host material, BD is used as a doping material, and the mass ratio of BH to BD is approximately 98:2. The second light-emitting layer has a thickness of approximately 20 nm.

S12, vacuum-evaporating compound HB on the second light-emitting layer as the second hole blocking layer with a thickness of approximately 5 nm.

S13, vacuum evaporating compounds ET and Alq3 on the second hole blocking layer as the second electron transport layer. The mass ratio of ET to Alq3 is approximately 1:1, and the second electron transport layer has a thickness of approximately 30 nm.

S14, vacuum evaporating Yb on the second electron transport layer as the electron injection layer with a thickness of approximately 1 nm.

S15, vacuum evaporating a magnesium-silver electrode as the cathode on the electron injection layer, with a mass ratio of Mg to Ag being approximately 1:9 and a thickness of approximately 14 nm.

S16, vacuum evaporating compound CPL, as the cap layer, on the cathode to obtain the tandem OLED device. The cap layer has a thickness of approximately 70 nm

The structures of the compounds PD, HB, BD, ET, Alq3, CPL, BH, PCGL and NCGL in the tandem OLED device are shown in Formulas PD, HB, BD, ET, Alq3, CPL, BH, PCGL and NCGL, respectively.

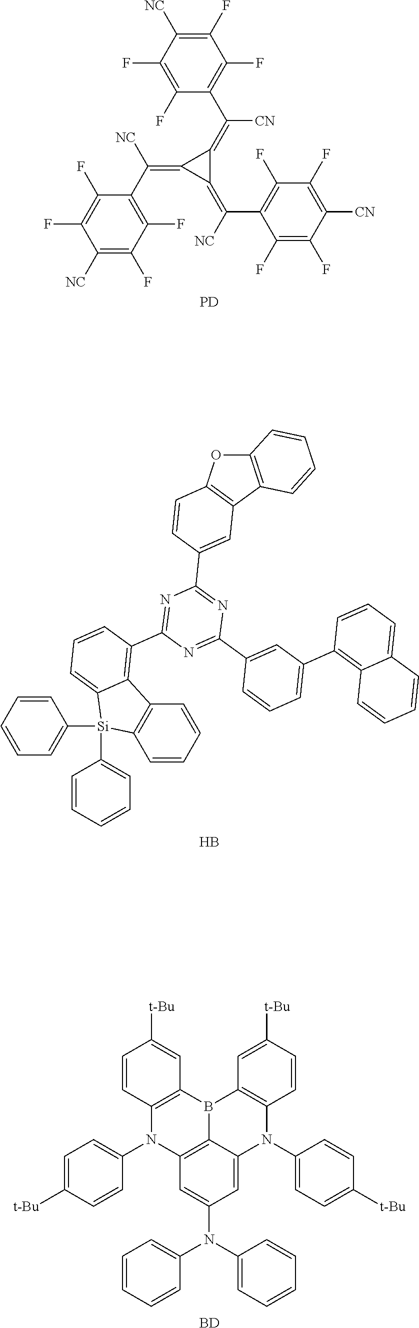

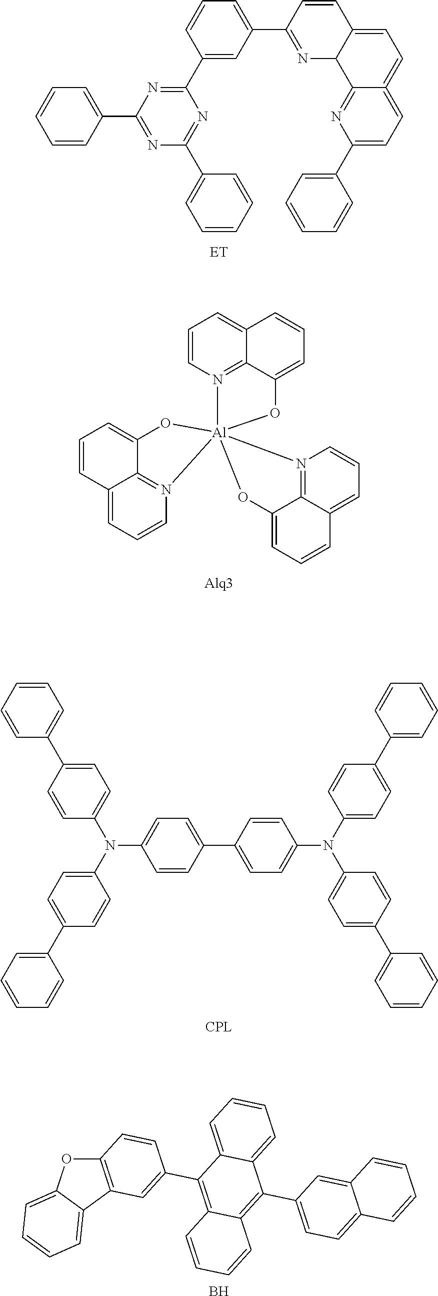

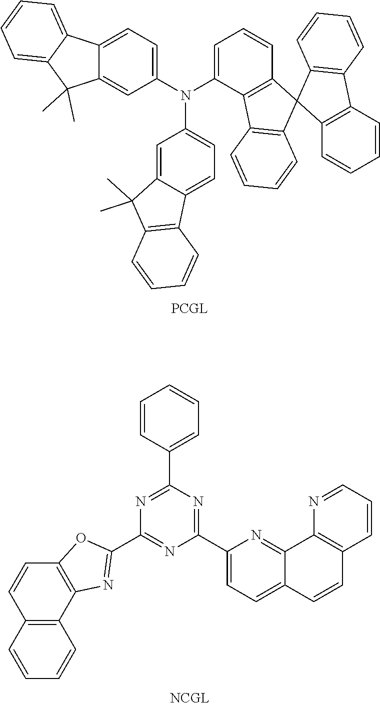 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; c1ccc(-c2nc(-c3ccc4ccc5cccnc5c4n3)nc(-c3nc4c(ccc5ccccc54)o3)n2)cc1]

Embodiments 2-10: one difference between Embodiments 2-10 and Embodiment 1 is that the material used for the middle layer in S8 is different. Details are listed in Table 1.

TABLE 1

| | | N-type | P-type | | | | |
|---|---|---|---|---|---|---|---|
| | | charge | charge | | | LT95@ | |
| | Middle | generation | generation | Von | BI | 85° C. | ΔV |
| | Layer | layer | layer | (V) | (cd/A/CIEy) | (h) | (V) |
| Embodiment | I-1 | I-1 | II-49 | 97.1% | 103.4% | 125.2% | 54.2% |
| 1 | | | | | | | |
| Embodiment | I-5 | I-1 | II-49 | 97.5% | 102.9% | 128.7% | 56.7% |
| 2 | | | | | | | |
| Embodiment | I-9 | I-1 | II-49 | 97.3% | 103.1% | 130.3% | 62.0% |
| 3 | | | | | | | |
| Embodiment | I-13 | I-1 | II-49 | 97.8% | 102.5% | 136.8% | 59.8% |
| 4 | | | | | | | |
| Embodiment | I-17 | I-1 | II-49 | 98.0% | 103.9% | 129.2% | 64.1% |
| 5 | | | | | | | |
| Embodiment | II-1 | I-1 | II-49 | 98.2% | 104.1% | 121.5% | 58.7% |
| 6 | | | | | | | |
| Embodiment | II-9 | I-1 | II-49 | 98.4% | 102.8% | 131.5% | 57.4% |
| 7 | | | | | | | |
| Embodiment | II-19 | I-1 | II-49 | 98.0% | 104.5% | 126.8% | 60.4% |
| 8 | | | | | | | |
| Embodiment | II-39 | I-1 | II-49 | 98.1% | 102.8% | 136.4% | 61.3% |
| 9 | | | | | | | |
| Embodiment | II-49 | I-1 | II-49 | 97.3% | 103.8% | 127.9% | 53.9% |
| 10 | | | | | | | |
| Embodiment | I-1/II-49 | I-1 | II-49 | 98.7% | 102.7% | 113.2% | 78.5% |
| 11 | | | | | | | |
| Embodiment | Ti | I-1 | II-49 | 97.0% | 101.4% | 112.6% | 74.8% |
| 12 | | | | | | | |
| Comparative | / | I-1 | II-49 | 100% | 100% | 100% | 100% |
| Embodiment | | | | | | | |
| 1 | | | | | | | |

Embodiment 11: one difference between Embodiment 11 and Embodiment 1 is that the material used for the intermediate layer in S8 is different. For Embodiment 11, S8 includes: sequentially vacuum evaporating NCGL I-1 (approximately 7.5 Å thick) and PCGL II-49 (approximately 7.5 Å thick) on the N-type charge generation layer as the intermediate layer.

Embodiment 12: one difference between Embodiment 12 and Embodiment 1 is that, in Embodiment 12, the intermediate layer in S8 is a Ti metal thin layer. For Embodiment 12, S8 includes: vacuum-evaporating a Ti metal layer with a thickness of approximately 15 Å on the N-type charge generation layer, as the intermediate layer.

Embodiments 13-15: one difference between Embodiments 13-15 and Embodiment 1 is that in S12, the materials of the second hole blocking layer vacuum-evaporated are different. Details are listed in Table 2.

TABLE 2

| | Hole blocking layer | Von (V) | BI (cd/A/CIEy) | LT95 (h) | ΔV (V) |
|---|---|---|---|---|---|
| Embodiment 13 | 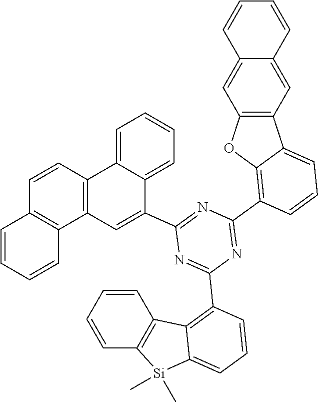 [SMILES: C[Si]1(C)c2ccccc2-c2c(-c3nc(-c4cc5c6ccccc6ccc5c5ccccc45)nc(-c4cccc5c4oc4cc6ccccc6cc45)n3)cccc21] | 96.8% | 104.8% | 122.1% | 56.5% |
| Embodiment 14 | 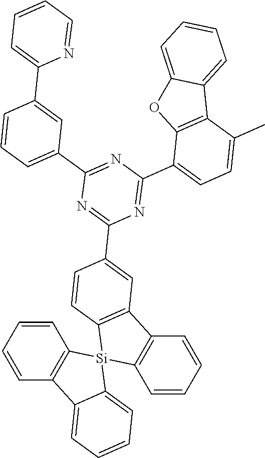 [SMILES: Cc1ccc(-c2nc(-c3cccc(-c4ccccn4)c3)nc(-c3ccc4c(c3)-c3ccccc3[Si]43c4ccccc4-c4ccccc43)n2)c2oc3ccccc3c12] | 97.0% | 105.2% | 120.9% | 55.8% |
| Embodiment 15 | 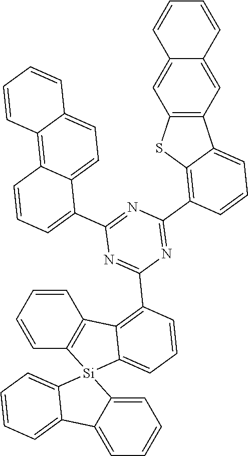 [SMILES: c1ccc2c(c1)-c1ccccc1[Si]21c2ccccc2-c2c(-c3nc(-c4cccc5c4ccc4ccccc45)nc(-c4cccc5c4sc4cc6ccccc6cc45)n3)cccc21] | 96.9% | 105.6% | 118.5% | 57.1% |

Embodiments 16-19: one difference between Embodiments 16-19 and Embodiment 1 is that in S12, the materials of the second hole blocking layer vacuum-evaporated are different. Details are listed in Table 3.

TABLE 3

| | | | BI | | |
|---|---|---|---|---|---|
| | | Von | (cd/A/ | LT95 | ΔV |
| | Hole blocking layer | (V) | CIEy) | (h) | (V) |
| Embodiment 16 | 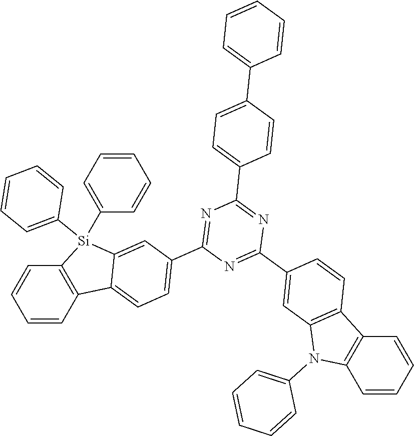 [SMILES: c1ccc(-c2ccc(-c3nc(-c4ccc5c(c4)[Si](c4ccccc4)(c4ccccc4)c4ccccc4-5)nc(-c4ccc5c6ccccc6n(-c6ccccc6)c5c4)n3)cc2)cc1] | 98.4% | 101.8% | 139.5% | 52.4% |
| Embodiment 17 | 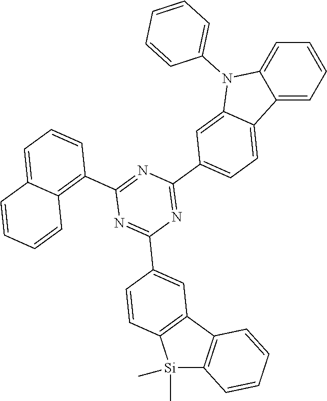 [SMILES: C[Si]1(C)c2ccccc2-c2cc(-c3nc(-c4ccc5c6ccccc6n(-c6ccccc6)c5c4)nc(-c4cccc5ccccc45)n3)ccc21] | 98.6% | 102.1% | 146.2% | 50.8% |
| Embodiment 18 | 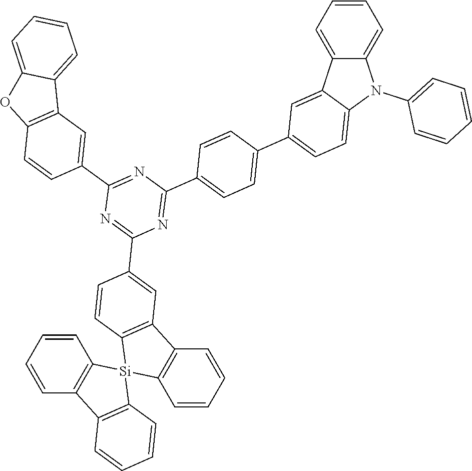 [SMILES: c1ccc(-n2c3ccccc3c3cc(-c4ccc(-c5nc(-c6ccc7c(c6)-c6ccccc6[Si]76c7ccccc7-c7ccccc76)nc(-c6ccc7oc8ccccc8c7c6)n5)cc4)ccc32)cc1] | 98.3% | 101.7% | 141.4% | 51.0% |
| Embodiment 19 | 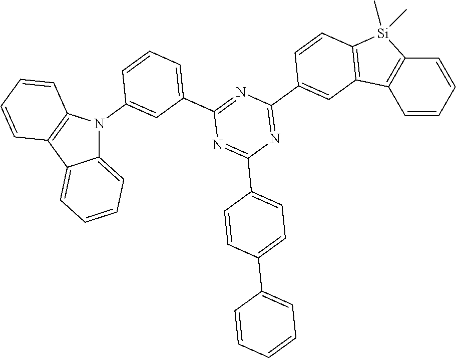 [SMILES: C[Si]1(C)c2ccccc2-c2cc(-c3nc(-c4ccc(-c5ccccc5)cc4)nc(-c4cccc(-n5c6ccccc6c6ccccc65)c4)n3)ccc21] | 98.7% | 101.3% | 150.4% | 49.5% |

Comparative Embodiment 1: one difference between Comparative Embodiment 1 and Embodiment 1 is that Comparative Embodiment 1 does not have an intermediate layer.

Performance evaluation of an OLED device: a Keithley 2365A digital nanovoltmeter was used to test the current of the OLED device at different voltages, and then the current density of the OLED device at different voltages was obtained by dividing the current by the light-emitting area. The brightness and radiant energy flux density of the OLED device at different voltages were tested using a Konicaminolta CS-2000 spectroradiometer. According to the current density and brightness of the OLED device at different voltages, the operating voltage (Von, in V) and BI value (current efficiency BI, in cd/A/CIEy) at a same current density (10 mA/cm²) were obtained. The high temperature lifespan LT95 was obtained by measuring the time when the brightness of the OLED device reached 95% of the initial brightness (under test conditions 85° C. and 50 mA/cm²). The drift voltage of the device was calculated according to the operating voltage of the device before and after the high temperature lifespan test (AV, the operating voltage difference of the device before and after the lifespan, AV=working voltage after high temperature lifespan-working voltage before high temperature lifespan, and the unit of AV is V). Taking the test values of V, BI, LT95@85° C., and AV of the device in Comparative Embodiment 1 as 100%, the ratios of the performance test values of other devices to the test values of the device in Comparative Embodiment 1 were calculated. The results are shown in Tables 1 and 2.

As shown in Table 1, compared with Comparative Embodiment 1, the organic light-emitting devices fabricated in Embodiments 1-19 have lower operating voltage, higher current efficiency, longer lifespan, and better device stability. Introducing the intermediate layer between the NCGL and PCGL structures may prevent metal diffusion in the N-type dopant and prevent the N-type dopant from directly contacting with the P-type dopant. As a result, the interface may not be reacted and destroyed, and the stability of the device may be improved. Moreover, the introduction of the intermediate layer may reduce the driving voltage of the device. Accordingly, while luminous brightness and current efficiency may be increased, power loss may be reduced, and device efficiency may be improved.

Compared with Embodiments 13-15, the organic light-emitting devices fabricated in Embodiments 16-19 may have a longer lifespan and device stability, and may have better application prospects in equipment with high requirements for lifespans, such as vehicle-mounted devices.

Compared with Embodiments 16-19, the organic light-emitting devices fabricated in Embodiments 13-15 may have a lower operating voltage and higher current efficiency, and may have better application prospects in mobile phones, tablets and other devices that have high requirements for reducing energy consumption.

As disclosed, the technical solutions of the present disclosure have the following advantages.

In the present disclosure, the charge generation layer includes an N-type charge generation layer (NCGL), an intermediate layer and a P-type charge generation layer (PCGL). The intermediate layer is disposed between the NCGL and the PCGL. Accordingly, the N-type dopant and the P-type dopant may be prevented from diffusing with each other, and the N-type dopant may be prevented from directly contacting with the P-type dopant. As a result, the interface may not be reacted and destroyed, and the interface stability may be improved. In addition, the intermediate layer may have functions of transmitting electrons and/or holes. Accordingly, the driving voltage of the device may be reduced, and the efficiency of the device may be improved.

The embodiments disclosed herein are exemplary only and not limiting the scope of the present disclosure. Various combinations, alternations, modifications, equivalents, or improvements to the technical solutions of the disclosed embodiments may be obvious to those skilled in the art. Without departing from the spirit and scope of this disclosure, such combinations, alternations, modifications, equivalents, or improvements to the disclosed embodiments are encompassed within the scope of the present disclosure.

What is claimed is:

1. An organic light-emitting device, comprising an anode, two or more light-emitting units,
and a cathode that are stacked one over another, wherein:
two adjacent light-emitting units of the two or more light-emitting units are connected through a charge generation layer;
the charge generation layer includes an N-type charge generation layer, an intermediate layer, and a P-type charge generation layer that are stacked one over another;
the N-type charge generation layer includes a first electron transport type organic material and an N-type dopant;
the P-type charge generation layer includes a first hole transport type organic material and a P-type dopant; and
the intermediate layer has a property of transporting electrons and/or holes.

2. The organic light-emitting device according to claim 1, wherein:
the intermediate layer includes a first material, wherein the first material includes a second electron transport type organic material and/or a second hole transport type organic material.

3. The organic light-emitting device according to claim 2, wherein:
the first material includes the second electron transport type organic material and the second hole transport type organic material, wherein the N-type charge generation layer, the second electron transport type organic material, the second hole transport type organic material, and the P-type charge generation layer are stacked in sequence.

4. The organic light-emitting device according to claim 2, wherein:
the first electron transport type organic material and the second electron transport type organic material are made of a same material; and/or
the first hole transport type organic material and the second hole transport type organic material are made of a same material.

5. The organic light-emitting device according to claim 1, wherein:
the intermediate layer includes a thin metal layer.

6. The organic light-emitting device according to claim 1, wherein:
the intermediate layer has a thickness in a range of approximately 5 to 200 Å.

7. The organic light-emitting device according to claim 1, wherein:
an energy level difference between a highest occupied molecular orbital (HOMO) energy level of the first hole transport type organic material and a lowest unoccupied molecular orbital (LUMO) energy level of the first electron transport type organic material is less than or equal to 0.8 ev.

8. The organic light-emitting device according to claim 7, wherein:
a light-emitting unit of the two or more light-emitting units includes an organic light-emitting layer and an electron transport layer, wherein the electron transport layer is disposed between the organic light-emitting layer and the N-type charge generation layer, or between the organic light-emitting layer and the cathode; and
an energy level difference between the LUMO energy level of the first electron transport type organic material and an LUMO energy level of the electron transport layer is less than or equal to 0.5 eV.

9. The organic light-emitting device according to claim 8, wherein:
the first electron transport type organic material has a structure shown in Formula (I): 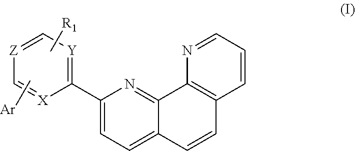
wherein:
X, Y, and Z are independently selected from one of C and N, and one or more of X, Y, and Z is N;
R₁ is selected from one or more of H, phenyl, pyridyl, and pyridylphenyl; and
Ar is selected from substituted or unsubstituted phenyl, anthracenyl, phenanthrenyl, pyrenyl, triphenylenyl, pyridyl, o-phenanthroline, naphthoxazolyl, naphthoimidazolyl, naphthothiazolyl, wherein a substituent is one or more of —CN, phenyl, and o-phenanthroline.

10. The organic light-emitting device according to claim 8, wherein:
a hole blocking layer is disposed between the organic light-emitting layer and the electron transport layer; and
an energy level difference between an LUMO energy level of the hole blocking layer and the LUMO energy level of the electron transport layer is greater than approximately 0.5 eV and not greater than approximately 1.0 eV.

11. The organic light-emitting device according to claim 10, wherein:
electron mobility of the hole blocking layer is smaller than electron mobility of the electron transport layer.

12. The organic light-emitting device according to claim 11, wherein:
the electron mobility of the hole blocking layer is in a range of approximately 1.0⁻⁹-1.0⁻⁸ cm²/Vs.

13. The organic light-emitting device according to claim 11, wherein:
the hole blocking layer includes a triazine-based bipolar electron transport material with one or more group of a triarylamine group, a carbazole group, and a phenoloxazine group.

14. The organic light-emitting device according to claim 13, wherein:
the triazine-based bipolar electron transport material is selected from one or more of structures shown in Formula (III) and Formula (IV): 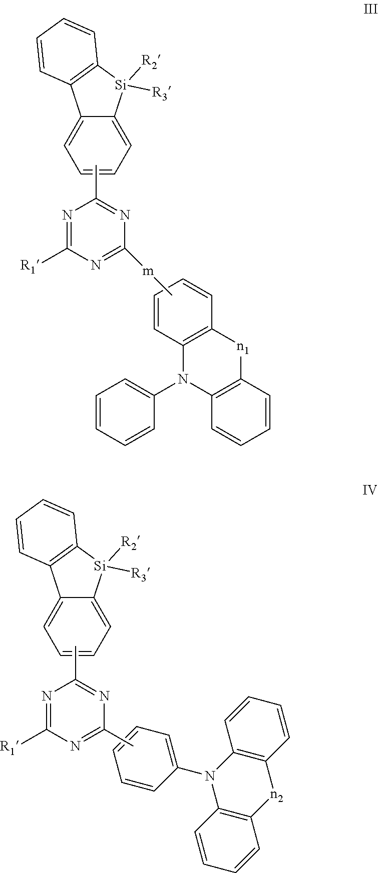
wherein:
R₁′ is selected from one of substituted or unsubstituted phenyl, naphthyl, and dibenzofuran, wherein a substituent is an aromatic group, and the aromatic group is selected from one of phenyl, biphenyl, and dibenzofuran;
R₂′ and R₃′ are independently selected from one of alkyl and phenyl; or R₂′ and R₃′ are independently selected from one of alkylene and phenylene, and R₂′, R₃′, and Si connected to R₂′ and R₃′ together form a five-membered ring;
m is selected from a single bond or a phenylene group;
n₁ is one of a single bond, an S atom or an O atom;
R₄′ is selected from one of substituted or unsubstituted phenyl, naphthyl, and dibenzofuran, wherein a substituent is an aromatic group, and the aromatic group is selected from one of phenyl, biphenyl, and dibenzofuran;
R₅′ and R₆′ are independently selected from one of alkyl and phenyl; or R₅′ and R₆′ are independently selected from one of alkylene and phenylene, and R₅′, R₆′, and Si connected to R₅' and R₆′ together form a five-membered ring; and
n₂ is selected from one of a single bond, an S atom or an O atom.

15. The organic light-emitting device according to claim 8, wherein:
a hole blocking layer is disposed between the organic light-emitting layer and the electron transport layer, wherein an energy level difference between an LUMO energy level of the hole blocking layer and the LUMO energy level of the electron transport layer is less than or equal to 0.4 eV.

16. The organic light-emitting device according to claim 15, wherein:
electron mobility of the hole blocking layer is in a range of approximately 1.0⁻⁷-1.0⁻⁶ cm²/Vs.

17. The organic light-emitting device according to claim 16, wherein:
the hole blocking layer includes a triazine-based strong electron transport material, wherein the triazine-based strong electron transport material has a structure shown in Formula (VI): 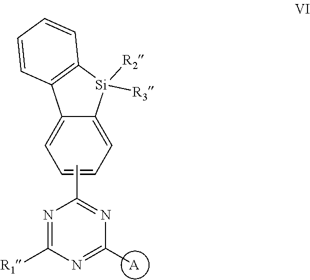
wherein:
A is selected from one of substituted or unsubstituted phenyl, biphenyl, naphthyl, anthracenyl, phenanthrenyl, triphenylene, azaphenanthrenyl, 9,9-dimethylacridinyl, dibenzofuranyl, and dibenzothiophenyl, wherein a substituent is one or more of phenyl, naphthyl, pyridyl, pyridylphenyl, and quinolyl;
R₁″ is selected from substituted or unsubstituted dibenzofuranyl and dibenzothiophenyl, wherein a substituent is one or more of an alkyl, a phenyl, and a phenylene group; and
R₂″ and R₃″ are independently selected from one of alkyl and phenyl; or R₂″ and R₃″ are independently selected from one of alkylene and phenyl, and R₂″, R₃″ and Si connected to R₂″ and R₃″ together form a five-membered ring.

18. The organic light-emitting device according to claim 1, wherein:
a thickness of the N-type charge generation layer is in a range of approximately 50-200 Å, and a thickness of the P-type charge generation layer is in a range of approximately 55-150 Å.

19. A display panel, comprising an organic light-emitting device, wherein the organic light-emitting device includes an anode, two or more light-emitting units, and a cathode that are stacked one over another, wherein:
two adjacent light-emitting units of the two or more light-emitting units are connected through a charge generation layer;
the charge generation layer includes an N-type charge generation layer, an intermediate layer, and a P-type charge generation layer that are stacked one over another;
the N-type charge generation layer includes a first electron transport type organic material and an N-type dopant;
the P-type charge generation layer includes a first hole transport type organic material and a P-type dopant; and
the intermediate layer has a property of transporting electrons and/or holes.

20. A display apparatus, comprising a display panel including an organic light-emitting device, wherein the organic light-emitting device includes an anode, two or more light-emitting units, and a cathode that are stacked one over another, wherein:
two adjacent light-emitting units of the two or more light-emitting units are connected through a charge generation layer;
the charge generation layer includes an N-type charge generation layer, an intermediate layer, and a P-type charge generation layer that are stacked one over another;
the N-type charge generation layer includes a first electron transport type organic material and an N-type dopant;
the P-type charge generation layer includes a first hole transport type organic material and a P-type dopant; and
the intermediate layer has a property of transporting electrons and/or holes.
